(19) United States
(12) Patent Application Publication
(10) Pub. No.: US 2025/0300043 A1
(43) Pub. Date: Sep. 25, 2025

(54) SEMICONDUCTOR DEVICE

(71) Applicant: Rohm Co., Ltd., Kyoto-shi (JP)

(72) Inventor: Hiroaki AOYAMA, Kyoto-shi (JP)

(21) Appl. No.: 19/230,844

(22) Filed: Jun. 6, 2025

Related U.S. Application Data
(63) Continuation of application No. PCT/JP2023/042902, filed on Nov. 30, 2023.

(30) Foreign Application Priority Data
Dec. 13, 2022 (JP) 2022-198667

(51) Int. Cl. H01L 23/495; H01L 23/31

(52) U.S. Cl. CPC H01L 23/49541; H01L 23/3107

(57) ABSTRACT

A semiconductor device includes a plurality of leads, a semiconductor element supported by the leads and connected to at one or more of the leads, and a sealing resin covering a part of each lead and the semiconductor element. As viewed in the thickness direction, the center of the semiconductor element is offset with respect to the center of the sealing resin in a first direction. The plurality of leads includes a first lead located closest to the first corner of the sealing resin on the one side of the first direction. The end face and the reverse surface of the first lead are exposed from the sealing resin. The area of the exposed reverse surface is greater than that of the reverse surface of a lead provided adjacent to the first lead.

### TECHNICAL FIELD

The present disclosure relates to semiconductor devices.

### BACKGROUND ART

Various configurations have been proposed for semiconductor devices equipped with semiconductor elements. One type of packaging for semiconductor devices is known as QFN (Quad For Non-Lead Package). JP-A-2020-77694 discloses an example of a semiconductor device with QFN. The semiconductor device disclosed in JP-A-2020-77694 has multiple leads, a semiconductor element, and a sealing resin. The semiconductor element is supported by the leads. The sealing resin covers a portion of each lead and the semiconductor element. The sealing resin and the semiconductor element are rectangular in plan view.

In the above semiconductor device, the end face of each lead is exposed so as to be flush with the side face of the sealing resin (the package member in JP-A-2020-77694). In addition, the reverse surface of each lead is exposed so as to be flush with the bottom face of the sealing resin. For this reason, compared to a QFP (Quad Flat Package) in which the leads protrude from the side faces of the sealing resin, the above-noted semiconductor device can be miniaturized, and thus the mounting area on the wiring board can be reduced.

In the above-noted QFN semiconductor device, the center of the semiconductor element may be offset from the center of the sealing resin in plan view. In this case, when mounting the semiconductor device on the wiring board, there may be a risk that the stresses generated in the respective solders joined to the reverse surfaces of the leads may be uneven. Then, during mounting of the semiconductor device, there may a risk that cracks (openings) will be formed in a solder where stress is concentrated, or that the solder will be unduly detached.

### BRIEF DESCRIPTION OF DRAWINGS

FIG. 1 is a perspective view showing a semiconductor device according to a first embodiment of the present disclosure.

FIG. 2 is a plan view (seen through the sealing resin) showing the semiconductor device according to the first embodiment of the present disclosure.

FIG. 3 is a plan view (seen through the semiconductor element and the sealing resin) showing the semiconductor device according to the first embodiment of the present disclosure.

FIG. 4 is a bottom view of the semiconductor device according to the first embodiment of the present disclosure.

FIG. 5 is a front view of the semiconductor device according to the first embodiment of the present disclosure.

FIG. 6 is a rear view of the semiconductor device according to the first embodiment of the present disclosure.

FIG. 7 is a right side view of the semiconductor device according to the first embodiment of the present disclosure.

FIG. 8 is a left side view of the semiconductor device according to the first embodiment of the present disclosure.

FIG. 9 is a partially enlarged view of FIG. 4.

FIG. 10 is a partially enlarged view of FIG. 4.

FIG. 11 is a cross-sectional view along line XI-XI in FIG. 3.

FIG. 12 is a cross-sectional view along line XII-XII in FIG. 3.

FIG. 13 is a cross-sectional view along line XIII-XIII in FIG. 3.

FIG. 14 is a cross-sectional view along line XIV-XIV in FIG. 3.

FIG. 15 is a cross-sectional view along line XV-XV in FIG. 3.

FIG. 16 is a plan view (seen through the semiconductor element and the sealing resin) of the semiconductor device according to a first variation of the first embodiment.

FIG. 17 is a bottom view of the semiconductor device according to the first variation of the first embodiment.

FIG. 18 is a right side view of the semiconductor device according to the first variation of the first embodiment.

FIG. 19 is a plan view (seen through the semiconductor element and the sealing resin) of a semiconductor device according to a second embodiment of the present disclosure.

FIG. 20 is a bottom view of the semiconductor device according to the second embodiment of the present disclosure.

FIG. 21 is a rear view of the semiconductor device according to the second embodiment of the present disclosure.

FIG. 22 is a right side view of the semiconductor device according to the second embodiment of the present disclosure.

FIG. 23 is a plan view (seen through the semiconductor element and the sealing resin) of the semiconductor device according to a first variation of the second embodiment.

FIG. 24 is a bottom view of the semiconductor device according to the first variation of the second embodiment.

FIG. 25 is a front view of the semiconductor device according to the first variation of the second embodiment.

FIG. 26 is a rear view of the semiconductor device according to the first variation of the second embodiment.

FIG. 27 is a right side view of the semiconductor device according to the first variation of the second embodiment.

FIG. 28 is a partially enlarged bottom view showing another configuration of the first lead.

FIG. 29 is a partially enlarged bottom view showing another configuration of the first lead.

### DETAILED DESCRIPTION OF EMBODIMENTS

The following specifically describes preferred embodiments of the present disclosure with reference to the drawings.

In the present disclosure, the terms such as “first”, “second”, “third”, and so on are used only as labels and not to imply any order of the items referred to by the terms.

In the present disclosure, the expressions “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expressions “An object A is arranged in an object B”, and “An object A is arranged on an object B” imply the situation where, unless otherwise specifically noted, “the object A is arranged directly in or on the object B”, and “the object A is arranged in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a portion of the object B”. Still further, the expression “An object A contains (or the material of an object A includes) a material C” implies the situation where, unless otherwise specifically noted, “the object A is made of (or the material of the object A is) the material C” or “the object A is mainly made of (or the material of the object A is) the material C”. Still further, “A surface A faces in a direction B (or toward a first side or an opposite second side in the direction B) is not limited, unless otherwise specifically noted, to the situation where the surface A forms an angle of 90° with the direction B but includes the situation where the surface A is inclined relative to the direction B.

### First Embodiment

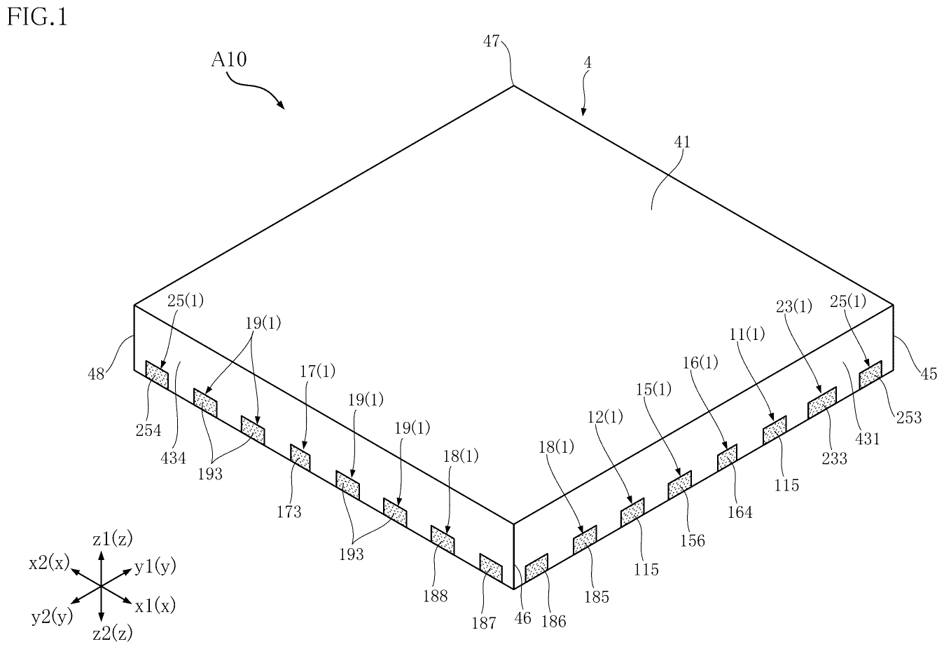

Referring to FIGS. 1 to 15, a semiconductor device according to a first embodiment of the present disclosure will be described. The semiconductor device A10 of the present embodiment includes a plurality of leads 1, a semiconductor element 3, and a sealing resin 4. As shown in FIG. 1, the packaging type of the semiconductor device A10 is a QFN (Quad For Non-Lead Package). The specific configuration of the semiconductor element 3 is not particularly limited, and the semiconductor element 3 is, for example, a flip-chip type LSI (Large Scale Integration) in which a switching circuit 321 and a control circuit 322 (to be described later) are configured internally. In the semiconductor device A10, the switching circuit 321 converts direct current power (voltage) into alternating current power (voltage). The semiconductor device A10 is used, for example, as a component constituting a circuit in a DC/DC converter.

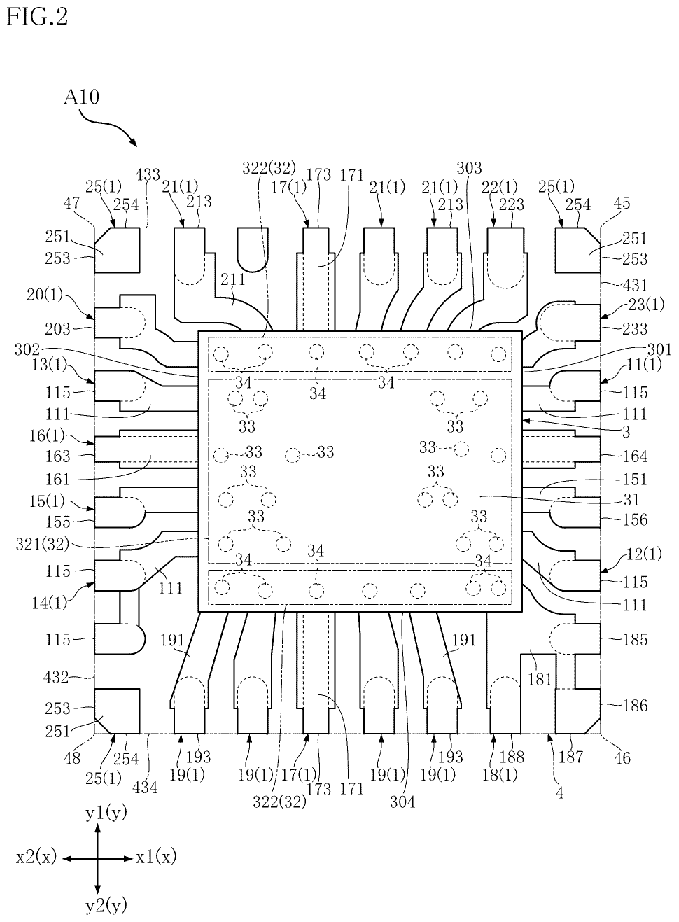

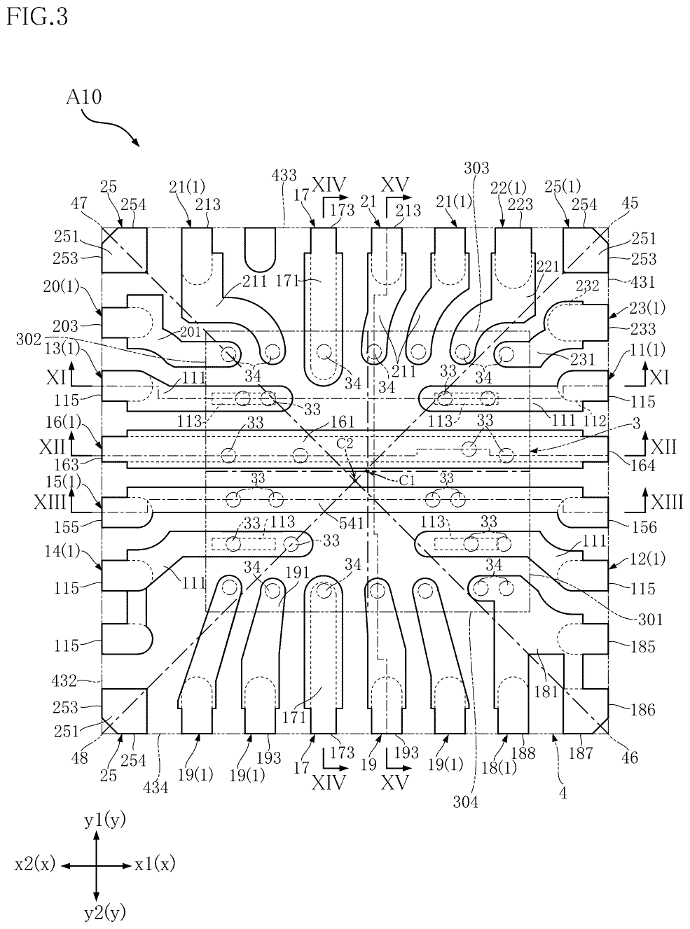

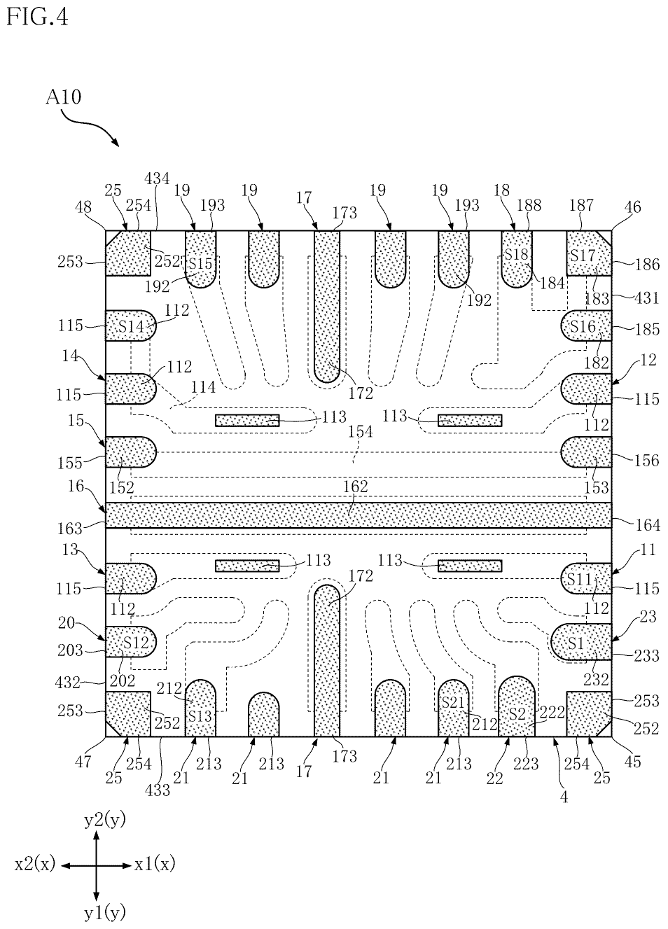

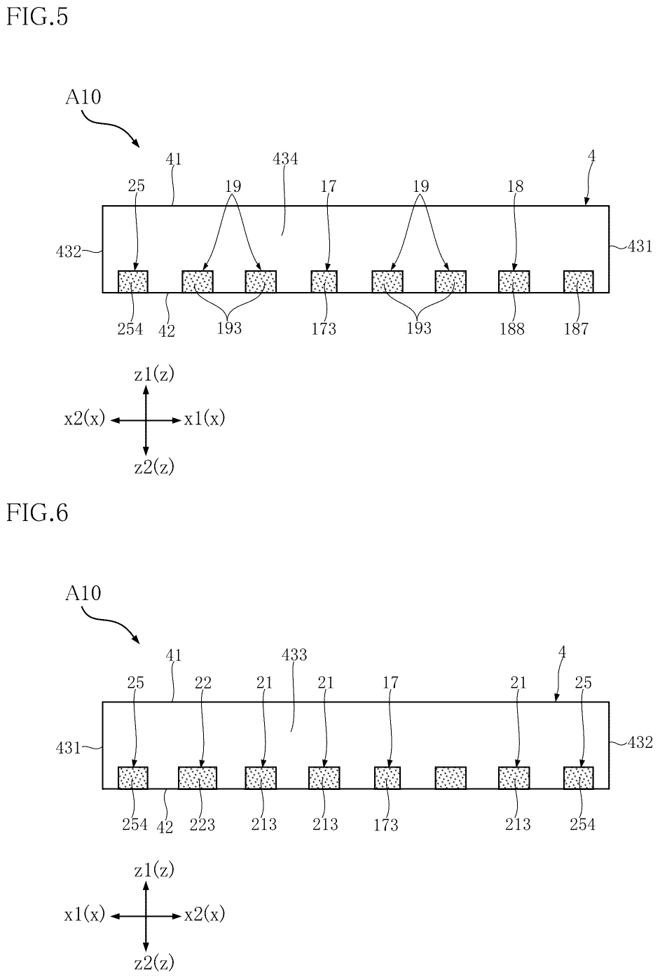

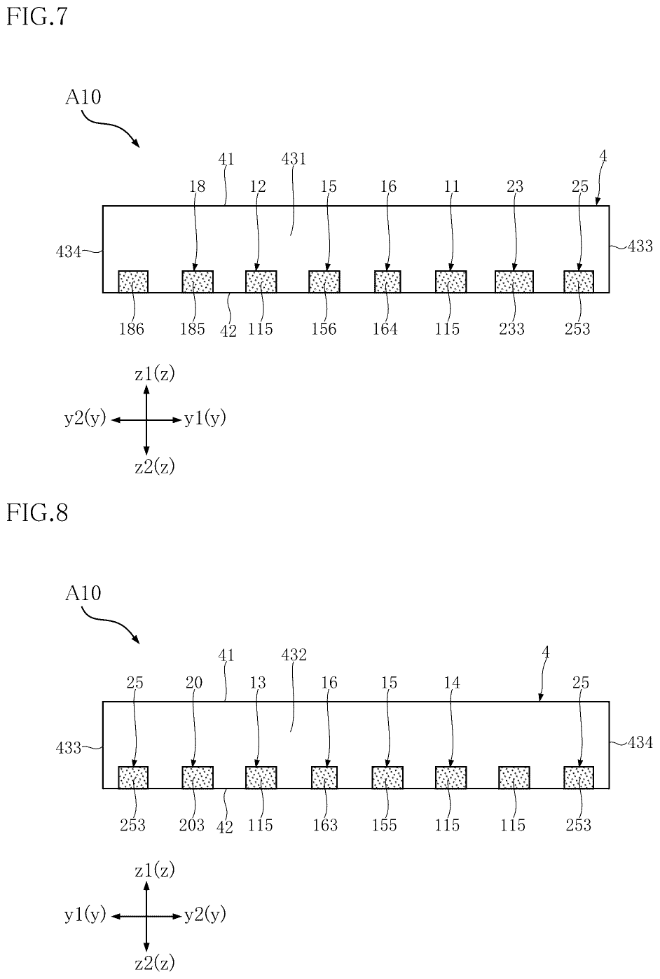

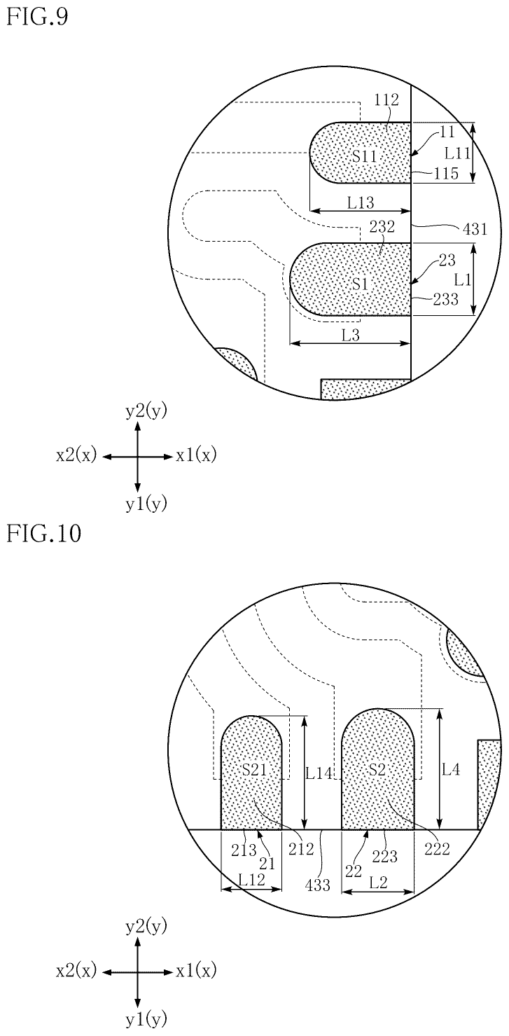

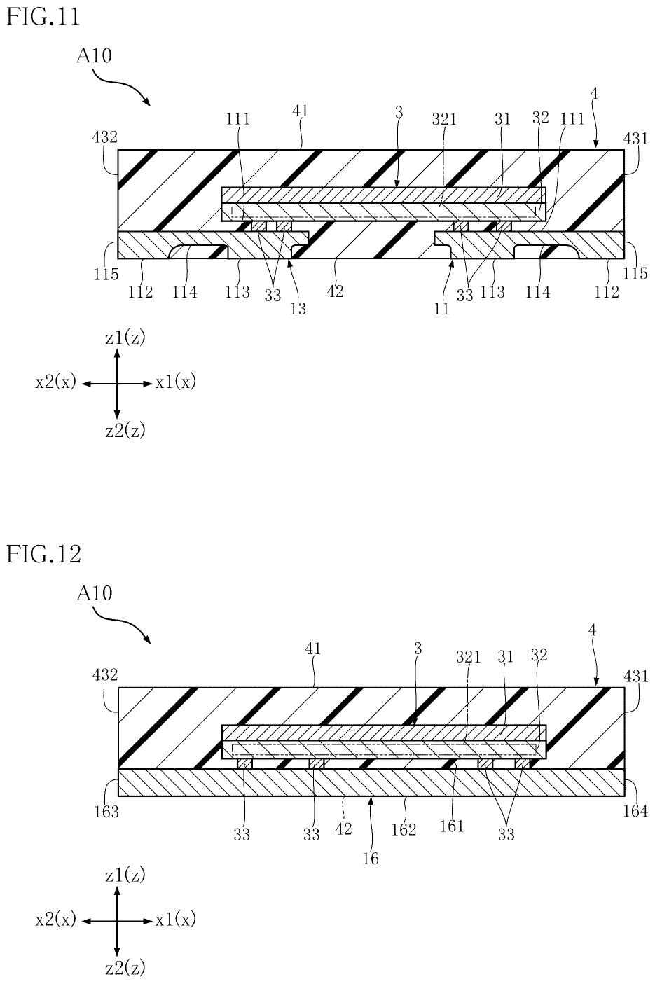

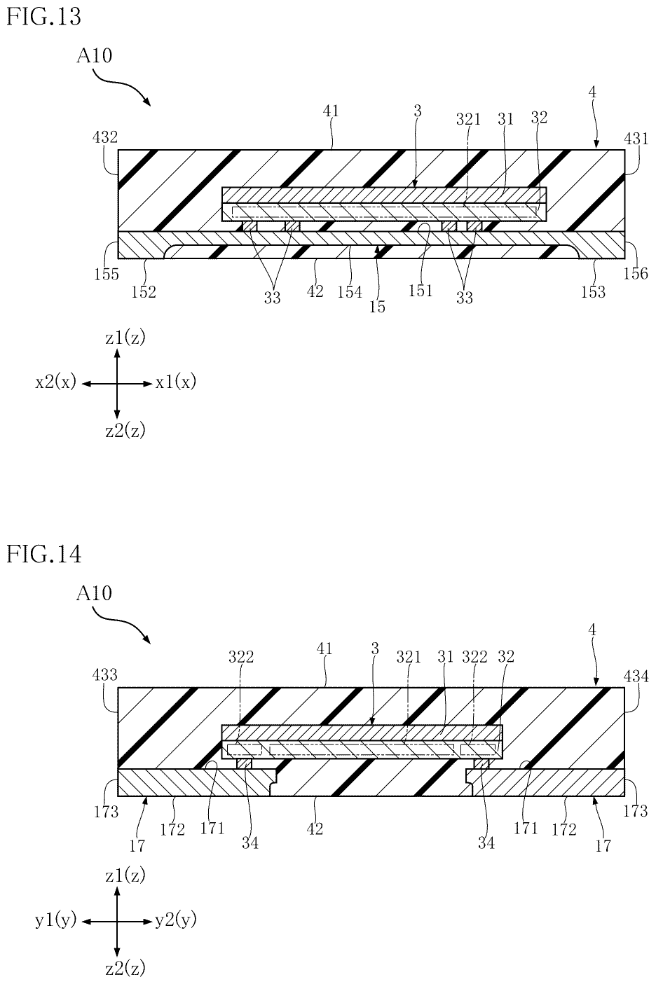

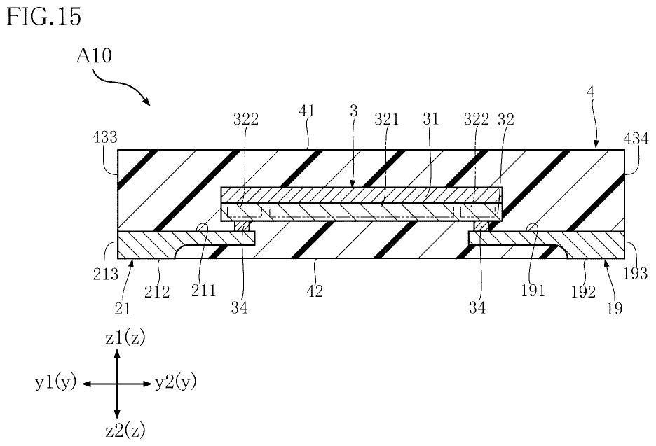

FIG. 1 is a perspective view showing the semiconductor device A10. FIG. 2 is a plan view showing the semiconductor device A10. FIG. 3 is a plan view showing the semiconductor device A10. FIG. 4 is a bottom view showing the semiconductor device A10. FIG. 5 is a front view showing the semiconductor device A10. FIG. 6 is a rear view showing the semiconductor device A10. FIG. 7 is a right side view of the semiconductor device A10. FIG. 8 is a left side view of the semiconductor device A10. FIGS. 9 and 10 are enlarged views of a portion of FIG. 4. FIG. 11 is a cross-sectional view along the line XI-XI in FIG. 3. FIG. 10 is a cross-sectional view along the line X-X in FIG. 3. FIG. 11 is a cross-sectional view along line XI-XI in FIG. 3. FIG. 12 is a cross-sectional view along line XII-XII in FIG. 3. FIG. 13 is a cross-sectional view along line XIII-XIII in FIG. 3. FIG. 14 is a cross-sectional view along line XIV-XIV in FIG. 3. FIG. 15 is a cross-sectional view along line XV-XV in FIG. 3. In FIG. 2, for ease of understanding, the sealing resin 4 is depicted as being transparent. In FIG. 3, for ease of understanding, the semiconductor element 3 and the sealing resin 4 are depicted as being transparent. In these figures, the semiconductor element 3 and the sealing resin 4 are shown by imaginary lines (double dotted lines).

In the description of the semiconductor device A10, the thickness direction (plan view direction) of each lead 1 is an example of the “thickness direction” in this disclosure and is referred to as “thickness direction z.” One direction perpendicular to the thickness direction z (the left-right direction in FIG. 2) is referred to as “first direction x.” The direction perpendicular to the thickness direction z and the first direction x (the up-down direction in FIG. 2) is called the “second direction y.” The illustrated semiconductor device A10 is rectangular as viewed in the thickness direction z. As shown in FIGS. 1 to 3, the semiconductor device A10 is square as viewed in the thickness direction z. In the description of the semiconductor device A10, the right side in FIG. 2 is an example of “one side of the first direction” in this disclosure and is called “the x1 side of the first direction x.” The left side in the figure is an example of “the other (or another) side of the first direction” in this disclosure and is called “the x2 side of the first direction x.” In FIG. 2, the upper side of the figure is an example of “one side of the second direction” in this disclosure and is referred to as “the y1 side of the second direction y.” The lower side of the figure is an example of “the other (or another) side of the second direction” in this disclosure and is referred to as “the y2 side of the second direction y.” In FIGS. 5 to 8, the upper side of the figure is an example of the “one side of the thickness direction” of the present disclosure, and is referred to as the “z1 side of the thickness direction z.” The lower side of the figure is an example of the “other (or another) side of the thickness direction” of the present disclosure, and is referred to as the “z2 side of the thickness direction z.”

As shown in FIG. 2, the plurality of leads 1 may include leads 11, 12, 13, 14, 15, 16, a pair of leads 17, a lead 18, a plurality of leads 19, a lead 20, a plurality of leads 21, leads 22, 23, and a plurality of leads 25. These leads 1 (i.e., leads 11-14, lead 15, lead 16, leads 17, lead 18, leads 19, lead 20, leads 21, lead 22 and lead 23) supports the semiconductor element 3, while serving as terminals for mounting the semiconductor device A10 on a circuit board, for example. As shown in FIGS. 2-4 and 11-15, each of the leads 11-14, 15, 16, 17, 18, 19, 20, 21, 22, 23 and 25 is partially covered by the sealing resin 4. The leads 11-14, 15, 16, 17, 18, 19, 20, 21, 22, 23 and 25 are produced from a common lead frame. The lead frame may be made of copper or copper alloy, for example.

As shown in FIGS. 3 and 4, the leads 11, 12, 13 and 14 are disposed on the x1 side or the x2 side of the semiconductor device A10 in the first direction x. In the illustrated embodiment, two (a pair of) leads 11, 12 are disposed on the x1 side of the first direction x, and the other two (a pair of) leads 13, 14 are disposed on the x2 side. In the illustrated embodiment, each of the leads 11-14 generally extends in the first direction x. The two leads 11, 12 on the x1 side are spaced apart from each other in the second direction y. Likewise, the two leads 13, 14 on the x2 side are spaced apart from each other in the second direction y. AC power (voltage) resulting from the power conversion by the switching circuit 321 of the semiconductor element 3 is outputted via the leads 11-14.

As shown in FIGS. 3, 4 and 11, each of the leads 11, 12, 13 and 14 has an obverse surface 111, a reverse surface 112, a reverse surface 113, a concave surface 114, and an end face 115. The obverse surface 111 faces the z1 side in the thickness direction z and faces the semiconductor element 3. The obverse surface 111 is covered with the sealing resin 4. The semiconductor element 3 is supported by the respective obverse surfaces 111.

The reverse surfaces 112, 113 and the concave surface 114 face the opposite side (the z2 side in the thickness direction z) of the obverse surface 111. The reverse surfaces 112 and 113 are spaced apart from each other, while sandwiching the concave surface 114 in the first direction x, and are exposed from the sealing resin 4. The concave surface 114 is displaced or offset toward the z1 side in the thickness direction z from the reverse surfaces 112, 113, thereby being closer to the obverse surface 111 than are the reverse surfaces 112, 113. The concave surface 114 is covered by the sealing resin 4. The end face 115 is connected to the obverse surface 111 and the reverse surface 112, facing the x1 side of the first direction x or the x2 side of the first direction x. The end face 115 is exposed from the sealing resin 4. As shown in FIG. 4, the lead 14 has two reverse surfaces 112 and two end faces 115. One reverse surface 112 and one end face 115 are spaced apart from the other reverse surface 112 and the other end face 115 in the second direction y.

In each lead 11 to 14, the obverse surface 111 on which the semiconductor element 3 is supported may be silver-plated, for example. The reverse surface 112, the reverse surface 113, and the end face 115 exposed from the sealing resin 4 may be tin-plated, for example. Instead of the tin plating, a plurality of metal plating layers may be used, for example, including nickel, palladium and gold layers in this order.

The lead 15 extends in the first direction x as shown in FIGS. 3 and 4. In this embodiment, the lead 15 is located at the center of of the semiconductor device A10 in the second direction y. The lead 15 is an input terminal via which DC power (voltage) to be converted by the semiconductor device A10 is inputted. The lead 15 is a positive terminal (P terminal).

As shown in FIG. 13, the lead 15 has an obverse surface 151, a reverse surface 152, a reverse surface 153, a concave surface 154, and an end face 156. The obverse surface 151 faces the same side of the thickness direction as the obverse surfaces 111 of the leads 11-14, while also facing the semiconductor element 3. The obverse surface 151 is covered with the sealing resin 4. The semiconductor element 3 is supported by the obverse surface 151.

The reverse surfaces 152, 153 and the concave surface 154 face the opposite side (the z2 side in the thickness direction z) of the obverse surface 151. The reverse surfaces 152 and 153 are spaced apart from each other in the first direction x with the concave surface 154 disposed therebetween and are exposed from the sealing resin 4. The reverse surface 152 is located on the x2 side of the first direction x, and the reverse surface 153 is located on the x1 side of the first direction x. The concave surface 154 is offset toward the z1 side in the thickness direction z than the reverse surfaces 152, 153, thereby being closer to the obverse surface 151 than are the reverse surfaces 152, 153. The concave surface 154 is covered by the sealing resin 4. The end face 155 is connected to the obverse surface 151 and the reverse surface 152 and faces the x2 side of the first direction x. The end face 156 is connected to the obverse surface 151 and the reverse surface 153 and faces the x1 side of the first direction x. The end faces 155 and 156 are exposed from the sealing resin 4.

In the lead 15, the obverse surface 151 on which the semiconductor element 3 is supported may be silver-plated, for example. The reverse surface 152, the reverse surface 153 and the end faces 155, 156 exposed from the sealing resin 4 may be tin-plated, for example. Instead of the tin plating, a plurality of metal plating layers may be used, for example, including nickel, palladium and gold layers in this order.

The lead 16 extends in the first direction x as shown in FIGS. 3 and 4. In this embodiment, the lead 16 is located at the center of the semiconductor device A10 in the second direction y. The lead 16 is an input terminal via which DC power (voltage) to be converted by the semiconductor device A10 is inputted. The lead 16 is a positive terminal (P terminal).

As shown in FIG. 12, the lead 16 has an obverse surface 161, a reverse surface 162, an end face 163, and an end face 164. The obverse surface 161 faces the same side as the obverse surfaces 111 of the leads 11-14 in the thickness direction z and faces the semiconductor element 3. The obverse surface 161 is covered with the sealing resin 4. The semiconductor element 3 is supported by the obverse surface 161.

The reverse surface 162 faces the opposite side of the obverse surface 161 (the z2 side in the thickness direction z). The reverse surface 162 is exposed from the sealing resin 4. In this embodiment, the obverse surface 161 and the reverse surface 162 extend along the entire length of the semiconductor device A10 in the first direction x. The end face 163 is connected to the obverse surface 161 and the reverse surface 162 and faces the x2 side of the first direction x. The end face 164 is connected to the obverse surface 161 and the reverse surface 162 and faces the x1 side of the first direction x. The end faces 163, 164 are exposed from the sealing resin 4.

In the lead 16, the obverse surface 161 on which the semiconductor element 3 is supported may be silver-plated, for example. The reverse surface 162, the end face 163 and the end face 164 exposed from the sealing resin 4 may be tin-plated, for example. Instead of the tin plating, a plurality of metal plating layers may be used, for example, including nickel, palladium and gold layers in this order.

The two leads 17 are disposed at the center of the semiconductor device A10 in the first direction x, as shown in FIGS. 3 and 4. Each lead 17 extends in the second direction y. One of the leads 17 is located on the y1 side of the second direction y, and the other lead 17 is located on the y2 side of the second direction y. Each lead 17 receives, for example, power (voltage) to drive the control circuit 322 or electrical signals to be transmitted to the control circuit 322.

As shown in FIG. 14, each lead 17 has an obverse surface 171, a reverse surface 172, and an end face 173. The obverse surface 171 faces the same side as the obverse surfaces 111 of the leads 11-14 in the thickness direction z and faces the semiconductor element 3. The obverse surface 171 is covered with the sealing resin 4. The semiconductor element 3 is supported by the obverse surface 171.

The reverse surface 172 faces the opposite side of the obverse surface 171 (the z2 side in the thickness direction z). The reverse surface 172 is exposed from the sealing resin 4. The end face 173 connects to the obverse surface 171 and the reverse surface 172 and faces the second direction y. Specifically, the end face 173 of one lead 17 faces the y1 side of the second direction y, and the end face 173 of the other lead 17 faces the y2 side of the second direction y. The end faces 173 are exposed from the sealing resin 4.

In the leads 17, the obverse surface 171 on which the semiconductor element 3 is supported may be silver-plated, for example. The reverse surface 172 and the end face 173 exposed from the sealing resin 4 may be tin-plated, for example. Instead of the tin plating, a plurality of metal plating layers may be used, for example, including nickel, palladium and gold layers in this order.

As shown in FIGS. 3 and 4, the lead 18 is disposed near the corner of the semiconductor device A10 which is on the x1 side of the first direction x and also on the y2 side of the second direction y. Electrical signals to be transmitted to the control circuit 322 may be inputted to the lead 18. The lead 18 has an obverse surface 181, three reverse surfaces 182, 183, 184, and four end faces 185, 186, 187, 188. The obverse surface 181 faces the same side as the obverse surfaces 111 of the leads 11 to 14 in the thickness direction z and faces the semiconductor element 3. The obverse surface 181 is covered with the sealing resin 4. The semiconductor element 3 is supported by the obverse surface 181. The reverse surfaces 182, 183, 184 face the opposite side of the obverse surface 181 (the z2 side in the thickness direction z). Each reverse surface 182-184 is exposed from the sealing resin 4. The reverse surface 183 is disposed at the corner of the semiconductor device A10 which is on the x1 side of the first direction x and on the y2 side of the second direction y. The reverse surface 182 is disposed adjacent to the reverse surface 183 on the y1 side in the second direction y. The reverse surface 184 is disposed adjacent to the reverse surface 183 on the x2 side in the first direction x. The end face 185 is connected to the obverse surface 181 and the reverse surface 182 and faces the x1 side in the first direction x. The end face 186 is connected to the obverse surface 181 and the reverse surface 183, and faces the x1 side of the first direction x. The end face 187 is connected to the obverse surface 181 and the reverse surface 183, and faces the y2 side of the second direction y. The end face 188 is connected to the obverse surface 181 and the reverse surface 184, and faces the y2 side of the second direction y. Each of the end faces 185-188 is exposed from the sealing resin 4.

In the lead 18, the obverse surface 181 on which the semiconductor element 3 is supported may be silver-plated, for example. The reverse surfaces 182-184 and the end faces 185-188 exposed from the sealing resin 4 may be tin-plated, for example. Instead of the tin plating, a plurality of metal plating layers may be used, for example, including nickel, palladium and gold layers in this order.

As shown in FIGS. 3 and 4, each lead 19 is disposed on the y2 side of the second direction y in the semiconductor device A10. The leads 19 are disposed at intervals in the first direction x. Electrical signals to be transmitted to the control circuit 322 may be inputted to each lead 19. As shown in FIGS. 3, 4 and 15, each lead 19 has an obverse surface 191, a reverse surface 192, and an end face 193. The obverse surface 191 faces the same side as the obverse surfaces 111 of the leads 11-14 in the thickness direction z and faces the semiconductor element 3. The obverse surface 191 is covered with the sealing resin 4. The semiconductor element 3 is supported by the obverse surface 191. The reverse surface 192 faces the opposite side of the obverse surface 191 (the z2 side in the thickness direction z). The reverse surface 192 is exposed from the sealing resin 4. The end face 193 is connected to the main surface 191 and the reverse surface 192, and faces the y2 side in the second direction y. The end face 193 is exposed from the sealing resin 4.

In each lead 19, the obverse surface 191 on which the semiconductor element 3 is supported may be plated with silver, for example. The reverse surface 192 and the end face 193 exposed from the sealing resin 4 may be plated with tin, for example. Instead of the tin plating, a plurality of metal plating layers may be used, for example, including nickel, palladium and gold layers in this order.

As shown in FIGS. 3 and 4, the lead 20 is disposed on the x2 side of the first direction x in the semiconductor device A10. The lead 20 is also disposed on the y1 side of the second direction y in the second direction y. Electrical signals to be transmitted to the control circuit 322 may be inputted to the lead 20. The lead 20 has an obverse surface 201, a reverse surface 202, and an end face 203. The obverse surface 201 faces the same side as the obverse surfaces 111 of the leads 11-14 in the thickness direction z and faces the semiconductor element 3. The obverse surface 201 is covered with the sealing resin 4. The semiconductor element 3 is supported by the obverse surface 201. The reverse surface 202 faces the opposite side of the obverse surface 201 (the z2 side in the thickness direction z). The reverse surface 202 is exposed from the sealing resin 4. The end face 203 is connected to the obverse surface 201 and the reverse surface 202, and faces the x2 side in the first direction x. The end face 203 is exposed from the sealing resin 4.

In the lead 20, the obverse surface 201 on which the semiconductor element 3 is supported may be silver-plated, for example. The reverse surface 202 and the end faces 203 exposed from the sealing resin 4 may be tin-plated, for example. Instead of the tin plating, a plurality of metal plating layers may be used, for example, including nickel, palladium and gold layers in this order.

As shown in FIGS. 3 and 4, each lead 21 is disposed on the y1 side of the second direction y in the semiconductor device A10. The leads 21 are disposed at intervals in the first direction x. Electrical signals to be transmitted to a control circuit 322 may be inputted to each lead 21. As shown in FIGS. 3, 4 and 15, each lead 21 has an obverse surface 211, a reverse surface 212, and an end face 213. The obverse surface 211 faces the same side as the obverse surfaces 111 of leads 11 to 14 in the thickness direction z and faces the semiconductor element 3. The obverse surface 211 is covered with the sealing resin 4. The semiconductor element 3 is supported by the obverse surface 211. The reverse surface 212 faces the opposite side of the obverse surface 211 (the z2 side in the thickness direction z). The reverse surface 212 is exposed from the sealing resin 4. The end face 213 is connected to the obverse surface 211 and the reverse surface 212, and faces the y1 side in the second direction y. The end face 213 is exposed from the sealing resin 4.

In each lead 21, the obverse surface 211 on which the semiconductor element 3 is supported may be silver-plated, for example. The reverse surface 212 and the end face 213 exposed from the sealing resin 4 may be tin-plated, for example. Instead of the tin plating, a plurality of metal plating layers may be used, for example, including nickel, palladium and gold layers in this order.

As shown in FIGS. 3 and 4, the lead 22 is disposed on the y1 side of the second direction y in the semiconductor device A10. The lead 22 is also disposed on the x1 side of the first direction x in the first direction x. Electrical signals to be transmitted to the control circuit 322 may be inputted to the lead 22. The lead 22 has an obverse surface 221, a reverse surface 222, and an end face 223. The obverse surface 221 faces the same side as the obverse surfaces 111 of the leads 11-14 in the thickness direction z and faces the semiconductor element 3. The obverse surface 221 is covered with the sealing resin 4. The semiconductor element 3 is supported by the obverse surface 221. The reverse surface 222 faces the opposite side of the obverse surface 221 (the z2 side in the thickness direction z). The reverse surface 222 is exposed from the sealing resin 4. The end face 223 is connected to the obverse surface 221 and the reverse surface 222, and faces the y1 side in the second direction y. The end face 223 is exposed from the sealing resin 4.

In the lead 22, the obverse surface 221 on which the semiconductor element 3 is supported may be plated with silver, for example. The reverse surface 222 and the end faces 223 exposed from the sealing resin 4 may be plated with tin, for example. Instead of the tin plating, a plurality of metal plating layers may be used, for example, including nickel, palladium and gold layers in this order.

As shown in FIGS. 3 and 4, the lead 23 is disposed on the x1 side of the first direction x in the semiconductor device A10. The lead 23 is also disposed on the y1 side of the second direction y in the second direction y. Electrical signals to be transmitted to the control circuit 322 may be inputted to the lead 23. The lead 23 has an obverse surface 231, a reverse surface 232, and an end face 233. The obverse surface 231 faces the same side as the obverse surfaces 111 of the leads 11-14 in the thickness direction z and faces the semiconductor element 3. The obverse surface 231 is covered with the sealing resin 4. The semiconductor element 3 is supported by the obverse surface 231. The reverse surface 232 faces the opposite side of the obverse surface 231 (the z2 side in the thickness direction z). The reverse surface 232 is exposed from the sealing resin 4. The end face 233 is connected to the obverse surface 231 and the reverse surface 232, and faces the x1 side in the first direction x. The end face 233 is exposed from the sealing resin 4.

In the lead 23, the obverse surface 231 on which the semiconductor element 3 is supported may be silver-plated, for example. The reverse surface 232 and the end face 233 exposed from the sealing resin 4 may be tin-plated, for example. Instead of the tin plating, a plurality of metal plating layers may be used, for example, including nickel, palladium and gold layers in this order.

As shown in FIGS. 3 and 4, each lead 25 is disposed at one of the four corners of the semiconductor device A10 as viewed in the thickness direction z (in plan view). This embodiment includes three leads 25. In the semiconductor device A10, a first lead 25 is positioned at the corner on the x1 side of the first direction x and on the y1 side of the second direction y. A second lead 25 is positioned at the corner on the x2 side of the first direction x and on the y1 side of the second direction y. A third lead 25 is disposed at the corner on the x2 side of the first direction x and on the y2 side of the second direction y. Each lead 25 is a dummy terminal, which is not electrically connected to the semiconductor element 3. Each lead 25 has an obverse surface 251, a reverse surface 252, an end face 253, and an end face 254. The obverse surface 251 faces the same side as the obverse surfaces 111 of the leads 11-14 in the thickness direction z. The obverse surface 251 is covered by the sealing resin 4. The reverse surface 252 faces the opposite side of the obverse surface 251 (the z2 side in the thickness direction z). The reverse surface 252 is exposed from the sealing resin 4. The end face 253 is connected to the obverse surface 251 and the reverse surface 252, and faces the first direction x. The end face 254 is connected to the obverse surface 251 and the reverse surface 252, and faces the second direction y. The end faces 253, 254 are exposed from the sealing resin 4.

In each lead 25, the reverse surface 252, the end face 253, and the end face 254 exposed from the sealing resin 4 may be tin-plated, for example. Instead of the tin plating, a plurality of metal plating layers may be used, for example, including nickel, palladium and gold layers in this order.

As shown in FIGS. 2, 11-15, the semiconductor element 3 is supported by the leads 11-14, the lead 15, the lead 16, the leads 17, the lead 18, the leads 19, the lead 20, the leads 21, the lead 22 and the lead 23. The semiconductor element 3 is covered with the sealing resin 4. The semiconductor element 3 may include a semiconductor substrate 31, a semiconductor layer 32, a plurality of electrodes 33 and a plurality of electrodes 34.

As shown in FIGS. 11-15, the semiconductor substrate 31 supports or holds the semiconductor layer 32, the electrodes 33 and the electrodes 34 on its lower side. The semiconductor substrate 31 is made of a material including, for example, silicon (Si) or silicon carbide (SiC).

The semiconductor layer 32 is formed on the semiconductor substrate 31 on the side facing e.g., the obverse surfaces 111 of the leads 11-14 in the thickness direction z. The semiconductor layer 32 may include various layers of p-type semiconductors and n-type semiconductors depending on the amount of doped elements. The semiconductor layer 32 comprises a switching circuit 321 and a control circuit 322 electrically connected to the switching circuit 321. The switching circuit 321 may be provided by, for example, a MOSFET (Metal-Oxide-Semiconductor Field-Effect Transistor) or an IGBT (Insulated Gate Bipolar Transistor). In the illustrated semiconductor device A10, the switching circuit 321 is divided into two regions: a high-voltage region (upper arm circuit) and a low-voltage region (lower arm circuit). Each region includes an n-channel MOSFET. The control circuit 322 may include a gate driver for driving the switching circuit 321, and a bootstrap circuit for the high voltage region of the switching circuit 321, and the control circuit 322 may perform control to drive the switching circuit 321 properly. A wiring (or connection) layer (not shown) may further be formed in the semiconductor layer 32, so that the switching circuit 321 and the control circuit 322 may be electrically connected to each other via the wiring layer.

As shown in FIGS. 11-15, the electrodes 33 and 34 are provided on the side facing e.g., the obverse surfaces 111 of the leads 11-14 in the thickness direction z. The electrodes 33, 34 are held in contact with the semiconductor layer 32.

Each electrode 33 is electrically connected to the switching circuit 321 of the semiconductor layer 32. Each electrode 33 is connected to a corresponding one of the obverse surfaces 111 of the leads 11-14, the obverse surface 151 of the lead 15, and the obverse surface 161 of the lead 16. Thus, the leads 11-14, the lead 15 and the lead 16 are electrically connected to the switching circuit 321. In the embodiment, as viewed in the thickness direction z, the respective reverse surfaces 113 of the leads 11-14 are located so as to overlap with at least one electrode 33.

Each electrode 34 is electrically connected to the control circuit 322 of the semiconductor layer 32. Each electrode 34 is connected to one of the obverse surfaces 171 of the leads 17, the obverse surface 181 of the lead 18, the obverse surfaces 191 of the leads 19, the obverse surface 201 of the lead 20, the obverse surfaces 211 of the leads 21, the obverse surface 221 of the lead 22, and the obverse surface 231 of the lead 23. As a result, the leads 17, 18, 19, 20, 21, 22 and 23 are electrically connected to the control circuit 322. The electrodes 33 and 34 may be made of a material including copper, for example.

As shown in FIGS. 2 and 3, the semiconductor element 3 has a rectangular shape as viewed in the thickness direction z. The semiconductor element 3 has a first element side surface 301, a second element side surface 302, a third element side surface 303, and a fourth element side surface 304. The first element side surface 301 and the second element side surface 302 are spaced apart from each other in the first direction x. The first element side surface 301 faces the x1 side of the first direction x. The second element side surface 302 faces the x2 side of the first direction x. The third element side surface 303 and the fourth element side surface 304 are connected to the first element side surface 301 and the second element side surface 302. The third element side surface 303 and the fourth element side surface 304 are spaced apart from each other in the second direction y. The third element side surface 303 faces the y1 side of the second direction y. The fourth element side surface 304 faces the y2 side of the second direction y. In this embodiment, as viewed in the thickness direction z, the semiconductor substrate 31 and the semiconductor layer 32 have their respective outer or peripheral side faces, and the combination of these side faces constitute the first element side surface 301, the second element side surface 302, the third element side surface 303, and the fourth element side surface 304.

As shown in FIGS. 5 to 8, the sealing resin 4 has a top face 41, a bottom face 42, a first side face 431, a second side face 432, a third side face 433, and a fourth side face 434. As shown in FIGS. 1 to 3, the sealing resin 4 has corners 45, 46, 47 and 48. The sealing resin 4 is rectangular as viewed in the thickness direction z. As shown in FIGS. 1 to 3, in the illustrated example, the sealing resin 4 is square as viewed in the thickness direction z. In this embodiment, the outer shape of the sealing resin 4, as viewed in the thickness direction z, matches the outer shape of the semiconductor device A10. The sealing resin 4 may be made of a material including, for example, a black epoxy resin.

As shown in FIGS. 11-15, the top face 41 faces the same side as the obverse surfaces 111 of the leads 11-14 in the thickness direction z. As shown in FIGS. 5-8, the bottom face 42 faces the opposite side of the top face 41. As shown in FIGS. 4 and 11-15, the following reverse surfaces are exposed from the bottom face 42, that is, the reverse surfaces 112, 113 of the leads 11-14, the reverse surfaces 152, 153 of the lead 15, the reverse surface 162 of the lead 16, the reverse surfaces 172 of the leads 17, the reverse surfaces 182, 183, 184 of the lead 18, the reverse surfaces 192 of the leads 19, the reverse surface 202 of the lead 20, the reverse surfaces 212 of the leads 21, the reverse surface 222 of the lead 22, the reverse surface 232 of the lead 23, and the reverse surfaces 252 of the leads 25.

As shown in FIGS. 5 and 6, the first side face 431 is connected to the top face 41 and the bottom face 42, and faces the x1 side of the first direction x. The second side face 432 is connected to the top face 41 and the bottom face 42, and faces the x2 side of the first direction x. The first side face 431 and the second side face 432 are spaced apart from each other in the first direction x. As shown in FIGS. 4, 7 and 11-13, the following end faces are exposed from the first side face 431. That is, the end faces 115 of the leads 11, 12, the end face 156 of the lead 15, the end face 164 of the lead 16, the end faces 185, 186 of the lead 18, the end face 233 of the lead 23, and the end face 253 of lead 25. These exposed end faces are flush with the first side face 431. Likewise, as shown in FIGS. 4, 8 and 11-13, the following end faces are exposed from the second side face 432. That is, the end faces of the leads 13, 14, the end face 155 of the lead 15, the end face 163 of the lead 16, the end face 203 of the lead 20, and the end faces 253 of the leads 25. These exposed end faces are flush with the second side face 432.

As shown in FIGS. 7 and 8, the third side face 433 is connected to the top face 41, the bottom face 42 and the first side faces 431, 432, and faces the y1 side of the second direction y.

The fourth side face 434 is connected to the top face 41, the bottom face 42 and the first side faces 431, 432, and faces the y2 side of the second direction y. The third side face 433 and the fourth side face 434 are spaced apart from each other in the second direction y. As shown in FIGS. 4, 6, 14 and 15, the end face 173 of one lead 17, the end faces 213 of the leads 21, the end face 223 of the lead 22, and the end faces 254 of the leads 25 are exposed from the third side face 433 in a manner being flush with the third side face 433.

Likewise, as shown in FIGS. 4, 5, 14 and 15, the end face 173 of the other lead 17, the end faces 187, 188 of the lead 18, the end faces 193 of the leads 19, and the end face 254 of the lead 25 are exposed from the fourth side face 434 in a manner being flush with the fourth side face 434.

Each corner 45, 46, 47 and 48 is located at one of the four corners of the sealing resin 4 having a square shape as viewed in the thickness direction z. The corners 45, 46 are located on the x1 side of the first direction x. Specifically, the corner 45 is located on the x1 side of the first direction x and on the y1 side of the second direction y, and at the intersection of the first side face 431 facing the x1 side and the third side face 433 facing the y1 side. The corner 46 is located on the x1 side of the first direction x and the y2 side of the second direction y, and at the intersection of the first side face 431 facing the x1 side and the fourth side face 434 facing the y2 side.

The corners 47, 48 are located on the x2 side of the first direction x. Specifically, the corner 47 is located on the x2 side of the first direction x and the y1 side of the second direction y, and at the intersection of the second side face 432 facing the x2 side and the third side face 433 facing the y1 side. The corner 48 is located on the x2 side of the first direction x and on the y2 side of the second direction y, and at the intersection of the second side face 432 facing the x2 side and the fourth side face 434 facing the y2 side.

In the semiconductor device A10, as shown in FIG. 3 or as viewed in the thickness direction z, the center C1 of the semiconductor element 3 is offset in the first direction x to the x1 side relative to the center C2 of the sealing resin 4. Further, in the illustrated example, the center C1 of the semiconductor element 3 is offset in the second direction y to the y1 side relative to the center C2 of the sealing resin 4.

In the embodiment, as shown in FIGS. 3 and 4, the leads 23 and 22 are located closest to the corner 45 of the sealing resin 4 among the plurality of leads 1 (leads 11-14, 15, 16, 17, 18, 19, 20, 21, 22, and 23) electrically connected to the semiconductor element 3.

As shown in FIG. 4, the area S1 of the reverse surface 232 of the lead 23 is larger than the area S11 of the reverse surface 112 of the lead 11. The lead 11 is adjacent to the lead 23 in the second direction y and is electrically connected to the semiconductor element 3. The area S1 of the reverse surface 232 of the lead 23 is larger than the area S12 of the reverse surface 202 of the lead 20, which is located closest to the corner 47 of the sealing resin 4 among the plurality of leads 1 electrically connected to the semiconductor element 3. The area S1 of the reverse surface 232 of the lead 23 is larger than the area S13 of the reverse surface 212 of the one lead 21 that is closest to the corner 47 among al the leads 21. This one lead 21 is closest to the corner 47 among all the leads 1 electrically connected to the semiconductor element 3.

The area S1 of the reverse surface 232 of the lead 23 is larger than the area S14 of the reverse surface 112 of the lead 14, which is located closest to the corner 48 of the sealing resin 4 among the leads 1 electrically connected to the semiconductor element 3. The area S1 of the reverse surface 232 of the lead 23 is larger than the area S15 of the reverse surface 192 of the one lead 19 that is located closest to the corner 48 among all the leads 19. This one lead 19 is located closest to the corner 48 among all the leads 1 electrically connected to the semiconductor element 3.

The area S1 of the reverse surface 232 of the lead 23 is larger than the area S16 of the reverse surface 182 of the lead 18. In addition, the area S1 of the reverse surface 232 is larger than the area S17 of the reverse surface 183 and larger than the area S18 of the reverse surface 184. The lead 18 is located closest to the corner 46 of the sealing resin 4 among all the leads 1 electrically connected to the semiconductor element 3.

As shown in FIGS. 3 and 4, the leads 20 and 23 are line-symmetrical in location with each other with respect to a straight line extending in the second direction y through the center C2 of the sealing resin 4 as viewed in the thickness direction z. The reverse surface 202 of the lead 20 overlaps with the reverse surface 232 of the lead 23 as viewed in the first direction x. As viewed in the thickness direction z, the lead 14 is point-symmetrical in location to the lead 23 with respect to the center C2 of the sealing resin 4.

In the above configurations, the corner 45 of the sealing resin 4 is an example of the “first corner” of the present disclosure, the corners 47, 48 of the sealing resin 4 are examples of the “second corner(s)” of the present disclosure, and the corner 46 of the sealing resin 4 is an example of the “third corner” of the present disclosure. The lead 23 is an example of the “first lead” of the present disclosure.

As shown in FIG. 4, the area S2 of the reverse surface 222 of the lead 22 is larger than the area S21 of the reverse surface 212 of the lead 21 located closest to the lead 21 among the plural leads 21. The lead 21 is adjacent to the lead 22 in the first direction x and is electrically connected to the semiconductor element 3. The area S2 of the reverse surface 222 of the lead 22 is larger than the area S12 of the reverse surface 202 of the lead 20, which is located closest to the corner 47 of the sealing resin 4 among the leads 1 electrically connected to the semiconductor element 3. The area S2 of the reverse surface 222 of the lead 22 is larger than the area S13 of the reverse surface 212 of the one lead 21 located closest to the corner 47 among all the leads 21. This one lead 21 is located closest to the corner 47 among all the leads 1 electrically connected to the semiconductor element 3.

The area S2 of the reverse surface 222 of the lead 22 is larger than the area S14 of the reverse surface 112 of the lead 14, which is located closest to the corner 48 of the sealing resin 4 among the leads 1 electrically connected to the semiconductor element 3. The area S2 of the reverse surface 222 of the lead 22 is larger than the area S15 of the reverse surface 192 of the one lead 19 located closest to the corner 48 among all the leads 19. This one lead 19 is located closest to the corner 48 among the leads 1 electrically connected to the semiconductor element 3.

The area S2 of the reverse surface 222 of the lead 22 is larger than the area S16 of the reverse surface 182 of the lead 18. In addition, the area S2 of the reverse surface 232 is larger than the area S17 of the reverse surface 183 and larger than the area S18 of the reverse surface 184. The lead 18 is located closest to the corner 46 of the sealing resin 4 among the leads 1 electrically connected to the semiconductor element 3.

As shown in FIGS. 3 and 4, the leads 21 include one lead 21 located closest to the corner 47, and this one lead 21 is line-symmetrical in location to the lead 22 with respect to a line passing through the center C2 of the sealing resin 4 as viewed in the thickness direction z and extending along the second direction y. The reverse surface 212 of the one lead 21 overlaps the reverse surface 222 of the lead 22 as viewed in the first direction x. The leads 19 include one lead 19 located closest to the corner 48, and this one lead 19 is point-symmetrical in location, with respect to the center C2 of the sealing resin 4 as viewed in the thickness direction z, to the lead 22. In the above configuration, the lead 22 is an example of the “first lead” of the present disclosure.

As shown in FIG. 9, the width dimension L1 of the reverse surface 232 of the lead 23 is larger than the width dimension L11 of the reverse surface 112 of the lead 11 located adjacent to the lead 23. The width direction of the reverse surface 232 is the direction (second direction y) along or parallel to the end face 233 as viewed in the thickness direction z. The width direction of the reverse surface 112 of the lead 11 is the direction (second direction y) along the end face 115 as viewed in the thickness direction z. As shown in FIG. 4, the width dimension L1 of the reverse surface 232 is larger than the width dimension of the reverse surface 202 of the lead 20 located closest to the corner 47 (second corner). The width direction of the reverse surface 202 in the lead 20 is the direction (second direction y) along the end face 223 as viewed in the thickness direction z. The width dimension L1 of the reverse surface 232 is larger than the width dimension of the reverse surface 212 of the lead 21 located closest to the corner 47 (second corner). The width direction of the reverse surface 212 of the lead 21 is the direction (first direction x) along the end face 213 as viewed in the thickness direction z. The width dimension L1 of the reverse surface 232 is larger than the width dimension of the reverse surface 112 of the lead 14 located closest to the corner 48 (second corner). The width of the reverse surface 112 of the lead 14 is the direction (second direction y) along the end face 115 as viewed in the thickness direction z. The width dimension L1 of the reverse surface 232 is larger than the width dimension of the reverse surface 192 of the lead 19 located closest to the corner 48 (second corner). The width direction of the reverse surface 192 of the lead 19 is the direction (first direction x) along the end face 193 as viewed in the thickness direction z.

As shown in FIG. 10, the width dimension L2 of the reverse surface 222 of the lead 22 is larger than the width dimension L12 of the reverse surface 212 of the lead 21 located adjacent to the lead 22. The width direction of the reverse surface 222 is the direction (first direction x) along the end face 223 as viewed in the thickness direction z, and the width direction of the reverse surface 212 of the lead 21 is the direction (first direction x) along the end face 213 as viewed in the thickness direction z. As shown in FIG. 4, the width dimension L2 of the reverse surface 222 is larger than the width dimension (in the second direction y) of the reverse surface 202 of the lead 20 located closest to the corner 47 (second corner). Further, the width dimension L2 of the reverse surface 222 is larger than the width dimension (in the first direction x) of the reverse surface 212 of the lead 21 located closest to the corner 47 (second corner). The width dimension L2 of the reverse surface 222 is larger than the width dimension (in the second direction y) of the reverse surface 112 of the lead 14 located closest to the corner 48 (second corner). The width dimension L2 of the reverse surface 222 is larger than the width dimension (in the first direction x) of the reverse surface 192 of the lead 19 located closest to the corner 48 (second corner).

As shown in FIG. 9, the depth dimension L3 of the reverse surface 232 of the lead 23 is larger than the depth dimension L13 of the reverse surface 112 of the lead 11 located adjacent to the lead 23. The depth direction of the reverse surface 232 is the direction (first direction x) perpendicular to the direction (second direction y) along the end face 233 as viewed in the thickness direction z, and the depth direction of the reverse surface 112 of the lead 11 is the direction (first direction x) perpendicular to the end face 115 (second direction y) as viewed in the thickness direction z. As shown in FIG. 4, the depth dimension L3 of the reverse surface 232 is larger than the depth dimension of the reverse surface 202 of the lead 20 located closest to the corner 47 (second corner). The depth direction of the reverse surface 202 of the lead 20 is the direction (first direction x) perpendicular to the direction (second direction y) along the end face 223 as viewed in the thickness direction z. The depth dimension L3 of the reverse surface 232 is larger than the depth dimension of the reverse surface 212 of the lead 21 located closest to the corner 47 (second corner). The depth direction of the reverse surface 212 of the lead 21 is, as viewed in the thickness direction z, the direction (second direction y) perpendicular to the direction (first direction x) along the end face 213. The depth dimension L3 of the reverse surface 232 is larger than the depth dimension of the reverse surface 112 of the lead 14 located closest to the corner 48 (second corner). The depth direction of the reverse surface 112 of the lead 14 is the direction (first direction x) perpendicular to the end face 115 (second direction y) as viewed in the thickness direction z. The depth dimension L3 of the reverse surface 232 is larger than the depth dimension of the reverse surface 192 of the lead 19 located closest to the corner 48 (second corner). The depth direction of the reverse surface 192 of the lead 19 is, as viewed in the thickness direction z, the direction (second direction y) perpendicular to the direction (first direction x) along the end face 193.

As shown in FIG. 10, the depth dimension L4 of the reverse surface 222 of the lead 22 is larger than the depth dimension L14 of the reverse surface 212 of the lead 21 located adjacent to the lead 22. The depth direction of the reverse surface 222 is the direction (second direction y) perpendicular to the direction (first direction x) along the end face 223 as viewed in the thickness direction z. The depth direction of the reverse surface 212 of the lead 21 is the direction (second direction y) perpendicular to the direction (first direction x) along the end face 213 as viewed in the thickness direction z. As shown in FIG. 4, the depth dimension LA of the reverse surface 222 is larger than the depth dimension (first direction x) of the reverse surface 202 of the lead 20 located closest to the corner 47 (second corner). The depth dimension L4 of the reverse surface 222 is larger than the depth dimension (second direction y) of the reverse surface 212 of the lead 21 located closest to the corner 47 (second corner). The depth dimension L4 of the reverse surface 222 is larger than the depth dimension (first direction x) of the reverse surface 112 of the lead 14 located closest to the corner 48 (second corner). The depth dimension L4 of the reverse surface 222 is larger than the depth dimension (second direction y) of the reverse surface 192 of the lead 19 located closest to the corner 48 (second corner).

The effects of the present embodiment will be described below.

The semiconductor device A10 comprises a plurality of leads 1, a semiconductor element 3 supported by the leads 1 and electrically connected to at least one of the leads 1, and a sealing resin 4 covering a part of each lead 1 and at least a part of the semiconductor element 3. The sealing resin 4 is rectangular as viewed in the thickness direction z and has a bottom face 42, a first side face 431, a second side face 432, a third side face 433, a fourth side face 434, and corners 45-48. The corners 45 and 46 are located on the x1 side of the first direction x in the sealing resin 4. The corners 47 and 48 are located on the x2 side of the first direction x in the sealing resin 4. As viewed in the thickness direction z, the center C1 of the semiconductor element 3 is offset toward the x1 side of the first direction x relative to the center C2 of the sealing resin 4. The leads 1 include leads 23 and 22 (first leads) that are located closest to the corner 45 (first corner) and are electrically connected to the semiconductor element 3. The lead 23 has a reverse surface 232 exposed from the bottom face 42 of the sealing resin 4, and an end face 233 extending to this reverse surface 232 and exposed from the first side face 431 of the sealing resin 4. The area S1 of the reverse surface 232 of the lead 23 is larger than the area S11 of the reverse surface 112 of the lead 11 located adjacent to the lead 23 and electrically connected to the semiconductor element 3. The area S1 of the reverse surface 232 of the lead 23 is larger than the areas S12 and S13 of the reverse surfaces 202 and 212 of the leads 20 and 21, which are located closest to the corner 47 (second corner) and electrically connected to the semiconductor element 3. The area S1 of the reverse surface 232 of the lead 23 is larger than the areas S14 and S15 of the reverse surfaces 112 and 192 of the leads 14 and 19, which are located closest to the corner 48 (second corner) and are electrically connected to the semiconductor element 3. With the above configuration, the semiconductor device may have an advantage as follows. It is supposed that the semiconductor element 3 has been disposed offset in a certain direction relative to the sealing resin 4, and there is a corner 45 located in that direction. Also, it is supposed that there is a lead 23 with a reverse surface 232 and an end face 233, located closest to the corner 45 and electrically connected to the semiconductor element 3. Now, with the above configuration, when mounting the semiconductor device A10 on a wiring circuit board for example, it is possible to provide a relatively large solder joint at the reverse surface 232 and/or the end face 233. As a result, during the mounting process of the semiconductor device A10, stress concentration at the solder joint present in the offset direction of the semiconductor element 3 can be suppressed, thereby improving the device mounting reliability by solder bonding.

The lead 22 has a reverse surface 222 exposed from the bottom face 42 of the sealing resin 4, and an end face 223 connected to the reverse surface 222 and exposed from the third side face 433 of the sealing resin 4. The area S2 of the reverse surface 222 of the lead 22 is larger than the area S21 of the reverse surface 212 of the lead 21 located adjacent to the lead 22 and electrically connected to the semiconductor element 3. The area S2 of the reverse surface 222 of the lead 22 is larger than the areas S12 and S13 of the reverse surfaces 202 and 212 of the leads 20 and 21, which are located closest to the corner 47 (second corner) and are electrically connected to the semiconductor element 3. The area S2 of the reverse surface 222 of the lead 22 is larger than the areas S14 and S15 of the reverse surfaces 112 and 192 of the leads 14 and 19, which are located closest to the corner 48 (second corner) and are electrically connected to the semiconductor element 3. With this configuration, as noted above, when mounting the semiconductor device A10 on a wiring circuit board, it is possible to provide a relatively large solder joint at the reverse surface 222 or the end face 223 of the lead 22, which is electrically connected to the semiconductor element 3 and closest to the corner 45 located in the direction in which the semiconductor element 3 is offset with respect to the sealing resin 4. As a result, during the mounting process of the semiconductor device A10, stress concentration at the solder joint present in the offset direction of the semiconductor element 3 can be suppressed, thereby improving the device mounting reliability by solder bonding.

In the semiconductor device A10, as viewed in the thickness direction z, the center C1 of the semiconductor element 3 is offset from the center C2 of the sealing resin 4 in the x1 direction of the first direction x and in the y1 direction of the second direction y. The corner 46 of the sealing resin 4 is located on the x1 side of the first direction x and on the y2 side of the second direction y. The area S1 of the reverse surface 232 of the lead 23 (first lead) is larger than the areas S16, S17 and S18 of the reverse surfaces 182, 183 and 184 of the lead 18, which is located closest to the corner 46 (third corner) and is electrically connected to the semiconductor element 3. The area S2 of the reverse surface 222 of the lead 22 (first lead) is larger than the areas S16, S17 and S18 of the reverse surfaces 182, 183 and 184 of the lead 18, which is located closest to the corner 46 (third corner) and electrically connected to the semiconductor element 3. With this configuration, when mounting the semiconductor device A10, solder stress concentration is more appropriately suppressed in the vicinity of the corner 45 located in the direction in which the semiconductor element 3 is offset (the x1 side of the first direction x and the x2 side of the first direction x), which is more desirable for improving mounting reliability.

In the embodiment shown in FIGS. 3 and 4, two leads 23 and 22 located closest to the corner 45 (first corner) of the sealing resin 4 may correspond to the “first lead” of the present disclosure, though the present disclosure is not limited to this. For instance, only one of the two leads 23 and 22 located closest to the corner 45 (first corner) may correspond to the first lead of the present disclosure. In this case, the area of the reverse surface of either one of the above two leads 23 and 22 may may be relatively large as described above.

### First Variation of First Embodiment

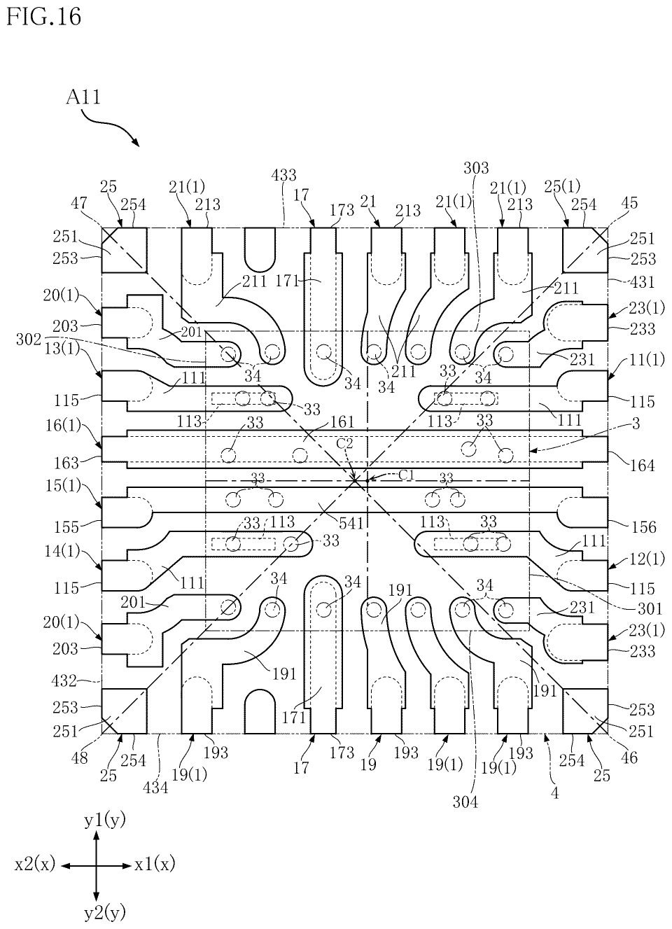

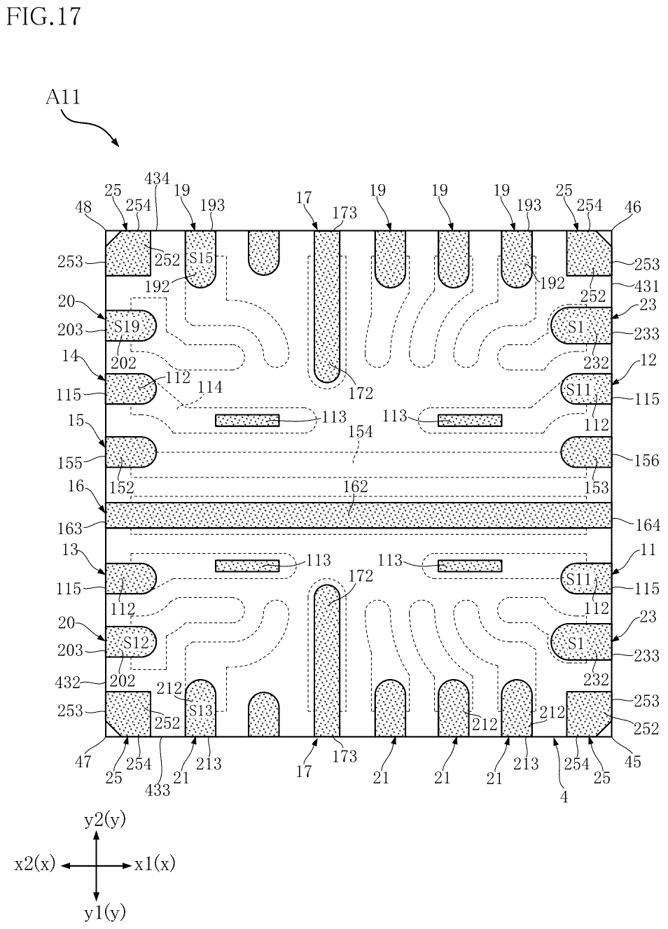

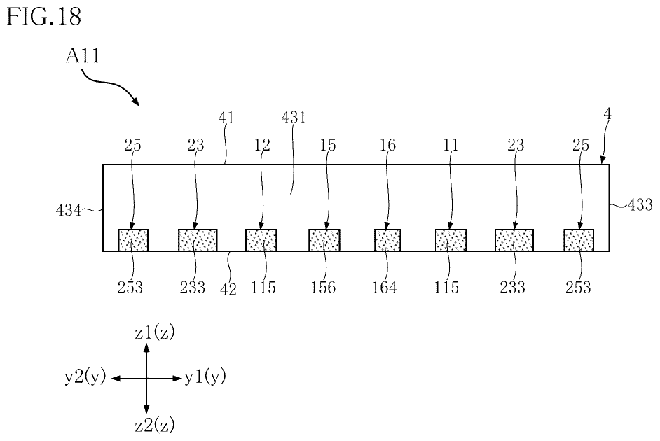

FIGS. 16-18 show a semiconductor device according to a first variation of the first embodiment. FIG. 16 is a plan view of the semiconductor device All of this variation. FIG. 17 is a bottom view of the semiconductor device A11. FIG. 18 is a right side view of the semiconductor device A11. For ease of understanding, the semiconductor element 3 and the sealing resin 4 are depicted as being transparent in FIG. 16. In FIG. 16, the semiconductor element 3 and the sealing resin 4 are shown by imaginary lines (two-dot lines). In FIG. 16 and the subsequent figures, elements identical or similar to those of the semiconductor device A10 of the first embodiment may be marked with the same reference numerals as in the first embodiment and explanations may be omitted where appropriate.

In the semiconductor device A11 of this variation, the arrangement of the semiconductor element 3 relative to the sealing resin 4 differs from that of the above embodiment. Further, the configuration and shapes of the leads 1 differ from those of the semiconductor device A10. In this variation, as viewed in the thickness direction z, the center C1 of the semiconductor element 3 is offset in the x1 direction of the first direction x relative to the center of the sealing resin 4. On the other hand, the center C1 of the semiconductor element 3 is not offset from the center C2 of the sealing resin 4 in the second direction y. As viewed in the thickness direction z, the center C1 of the semiconductor element 3 and the center C2 of the sealing resin 4 are located at the center of the semiconductor device A11 in the second direction y.

In this variation, the leads 1 include a plurality of leads 11-14, a lead 15, a lead 16, a pair of leads 17, a plurality of leads 19, a plurality of leads 20, a plurality of leads 21, a plurality of leads 23 and a plurality of leads 25. Further, the semiconductor device A11 includes two leads 23. As shown in FIGS. 16 and 17, the two leads 23 are disposed on the x1 side of the semiconductor device A11 in the first direction x. The two leads 23 are disposed on the y1 side and the y2 side, respectively, in the second direction y.

In the semiconductor device A11, the plurality of leads 1 also include four leads 25. These four leads 25 are located individually at the four corners of semiconductor device A11, respectively.

As shown in FIG. 17, the area S1 of the reverse surface 232 of the first lead 23 located on the y1 side of the second direction y is larger than the area S11 of the reverse surface 112 of the lead 11, which is located adjacent to the first lead 23 in the second direction y and is electrically connected to the semiconductor element 3. The area S1 of the reverse surface 232 of the second lead 23 located on the y2 side in the second direction y is larger than the area S11 of the reverse surface 112 of the lead 12, which is adjacent to the second lead 23 in the second direction y and is electrically connected to the semiconductor element 3. The area S1 of the reverse surface 232 of each lead 23 is larger than the area S12, S13 of the reverse surfaces 202, 212 of the leads 20, 21 located closest to the corner 47 of the sealing resin 4. The area S1 of the reverse surface 232 of each lead 23 is larger than the area S15, S19 of the reverse surface 192, 202 of the leads 19, 20 located closest to the corner 48 of the sealing resin 4.

In the configuration of the above variation, the corners 45 and 46 of the sealing resin 4 are examples of the “first corner(s)” of the present disclosure. The corners 47 and 48 of the sealing resin 4 are examples of the “second corner(s)” of the present disclosure. The two leads 23 are examples of the “first lead(s)” of the present disclosure.

The semiconductor device A11 comprises a plurality of leads 1, a semiconductor element 3 supported by the leads 1 and electrically connected to at least one of the leads 1, and a sealing resin 4 covering a part of each lead 1 and at least a part of the semiconductor element 3. The sealing resin 4 is rectangular as viewed in the thickness direction z and has a bottom face 42, a first side face 431, a second side face 432, a third side face 433, a fourth side face 434, and corners 45-48. The corners 45 and 46 are located on the x1 side of the first direction x in the sealing resin 4. The corners 47 and 48 are located on the x2 side of the first direction x in the sealing resin 4. As viewed in the thickness direction z, the center C1 of the semiconductor element 3 is offset toward the x1 side of the first direction x with respect to the center C2 of the sealing resin 4. The leads 1 include two leads 23 (first leads) located closest to the corners 45 and 46 (first corners), respectively, and electrically connected to the semiconductor element 3. Each lead 23 has a reverse surface 232 exposed from the bottom face 42 of the sealing resin 4 and an end face 233 connected to this reverse surface 232 and exposed from the first side face 431 of the sealing resin 4. The area S1 of the reverse surface 232 of the lead 23 is larger than the area S11 of the reverse surface 112 of the lead 11 (lead 12) located adjacent to the lead 23 and electrically connected to the semiconductor element 3. Further, The area S1 of the reverse surface 232 of the lead 23 is larger than the areas S12 and S13 of the reverse surfaces 202 and 212 of the leads 20 and 21, which are located closest to the corner 47 (second corner) and electrically connected to the semiconductor element 3. The area S1 of the reverse surface 232 of the lead 23 is larger than the areas S15 and S19 of the reverse surfaces 192 and 202 of the leads 19 and 20, which are located closest to the corner 48 (second corner) and electrically connected to the semiconductor element 3. With the above configuration, when mounting the semiconductor device All on a wiring circuit board, it is possible to provide relatively large solder joints at the reverse surfaces 232 and the end faces 233 of the two leads 23, which are closest to the corners 45 and 46 present in the direction in which the semiconductor element 3 is offset with respect to the sealing resin 4, and which are electrically connected to the semiconductor element 3. As a result, during the mounting process of the semiconductor device A11, stress concentration at the solder joint present in the offset direction of the semiconductor element 3 can be suppressed, thereby improving the device mounting reliability by solder bonding.

In the above variation shown in FIGS. 16 and 17, the lead 23 closest to the corner 45 (first corner) of the sealing resin 4 and the lead 23 closest to the corner 46 (first corner) may correspond to the “first lead” of the present disclosure, though the disclosure is not limited to this. Only one of the two leads 23 may correspond to the first lead of the present disclosure. In this case, the area of the reverse surface 232 of the one of the two leads 23 may be relatively large as described above.

### Second Embodiment

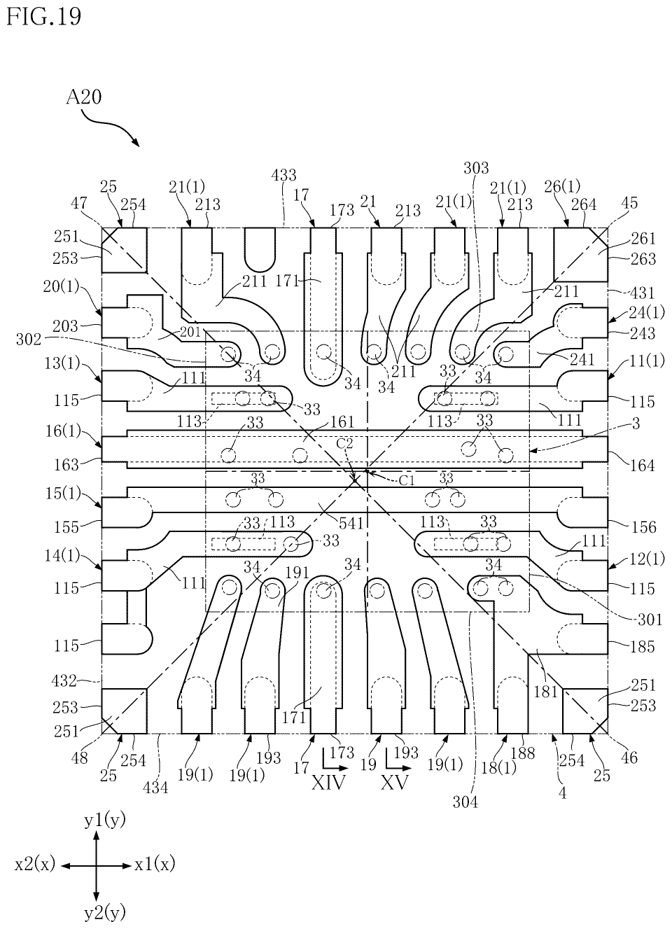

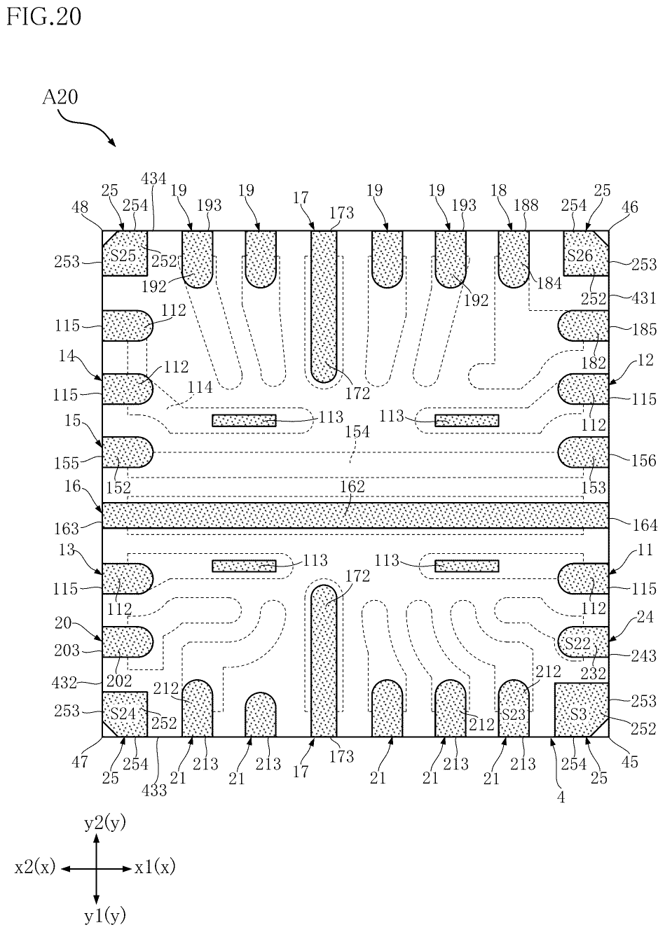

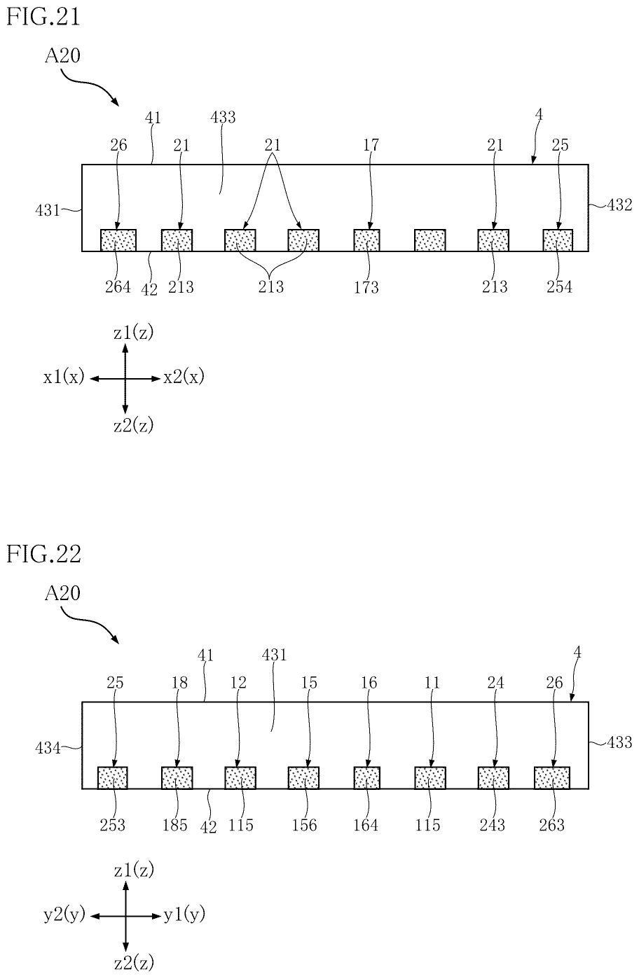

FIGS. 19 to 22 show a semiconductor device according to a second embodiment of the present disclosure. FIG. 19 is a plan view showing the semiconductor device A20 of the present embodiment. FIG. 20 is a bottom view of the semiconductor device A20. FIG. 21 is a rear view of the semiconductor device A20. FIG. 22 is a right side view of the semiconductor device A20. For ease of understanding, the semiconductor element 3 and the sealing resin 4 are depicted as being transparent, and indicated by imaginary lines (two-dot lines).

In the semiconductor device A20 of this embodiment, the configuration and shapes of the leads 1 differ from those of the semiconductor device A10 of the first embodiment. In the second embodiment, like the semiconductor device A10, as viewed in the thickness direction z, the center C1 of the semiconductor element 3 is offset from the center of the sealing resin 4 in the x1 direction of the first direction x and also in the y1 direction of the second direction y.

In the semiconductor device A20, the leads 1 include a plurality of leads 11, 12, 13, 14, a lead 15, a lead 16, a pair of leads 17, a lead 18, a plurality of leads 19, a lead 20, a plurality of leads 21, a lead 24, a plurality of leads 25, and a lead 26.

In the semiconductor device A20, the leads 1 include three leads 25. Each lead 25 is disposed at a corresponding one of the four corners of the semiconductor device A20. In the illustrated semiconductor device A20, the tree leads 25 are located at three corners, respectively, that is, a first corner on the x1 side of the first direction x and on the y2 side of the second direction y, a second corner on the x2 side of the first direction x and on the y1 side of the second direction y, and a third corner on the x2 side of the first direction x and on the y2 side of the second direction y.

The lead 26 is disposed at the corner of the semiconductor device A20 on the x1 side of the first direction x and on the y1 side of the second direction y. The lead 26 is located closest to the corner 45 among all the leads 1. The lead 26 is a dummy terminal, which is not electrically connected to the semiconductor element 3. The lead 26 has an obverse surface 261, a reverse surface 262, an end face 263, and an end face 264. The obverse surface 261 faces the same side as the obverse surfaces 111 of the leads 11-14 in the thickness direction z. The obverse surface 261 is covered with the sealing resin 4. The reverse surface 262 faces the opposite side of the obverse surface 261 (the z2 side in the thickness direction z). The reverse surface 262 is exposed from the bottom face 42 of the sealing resin 4. The end face 263 is connected to the obverse surface 261 and the reverse surface 262 and faces the first direction x. The end face 264 is connected to the obverse surface 261 and the reverse surface 262 and faces the second direction y. The end faces 263 and 264 are exposed from the sealing resin 4. In the first direction x, the lead 21 is disposed adjacent to the lead 26. In the second direction y, the lead 24 is disposed adjacent to the lead 26.

The lead 24 is disposed on the y2 side of the lead 26 in the second direction y. Electrical signals to be transmitted to the control circuit 322 may be inputted to the lead 24. The lead 24 has an obverse surface 241, a reverse surface 242, and an end face 243. The obverse surface 241 faces the same side as the obverse surfaces 111 of the leads 11-14 in the thickness direction z. The obverse surface 241 is covered with the sealing resin 4. The reverse surface 242 faces the opposite side of the obverse surface 241 (the z2 side in the thickness direction z). The reverse surface 242 is exposed from the bottom face 42 of the sealing resin 4. The end face 243 is connected to the obverse surface 241 and the reverse surface 242 and faces the x1 side in the first direction x. The end face 243 is exposed from the first side surface 431 of the sealing resin 4.

As shown in FIG. 20, the area S3 of the reverse surface 262 of the lead 26 is larger than the area S22 of the reverse surface 242 of the lead 24. The lead 24 is adjacent to the lead 26 in the second direction y. The area S3 of the reverse surface 262 of the lead 26 is larger than the area S23 of the reverse surface 212 of the lead 21, which is located closest to the corner 45 among the leads 21. The lead 21 is adjacent to the lead 26 in the first direction x.

The area S3 of the reverse surface 262 of the lead 26 is larger than the area S24 of the reverse surface 252 of the lead 25 located near the corner 47. The lead 25 is located closest to the corner 47 among the leads 1. The area S3 of the reverse surface 262 of the lead 26 is larger than the area S25 of the reverse surface 252 of the lead 25 located near the corner 48. The lead 25 is located closest to the corner 48 among the leads 1.

The area S3 of the reverse surface 262 of the lead 26 is larger than the area S26 of the reverse surface 252 of the lead 25 located near the corner 46. The lead 25 is located closest to the corner 46 among the leads 1.

As shown in FIGS. 19 and 20, the lead 25, located closest to the corner 47, is line-symmetrical in location to the lead 26, as viewed in the thickness direction z, with respect to a straight line passing through the center C2 of the sealing resin 4 and parallel to the second direction y. The reverse surface 252 of the lead 25 overlaps with the reverse surface 262 of the lead 26 as viewed in the first direction x. The lead 25, located closest to the corner 48, is point-symmetrical in location to the lead 26 with respect to the center C2 of the sealing resin 4 as viewed in the thickness direction z.

In the above configurations, the corner 45 of the sealing resin 4 is an example of the “first corner” of the present disclosure, the corners 47 and 48 of the sealing resin 4 are examples of the “second corner(s)” of the present disclosure, and the corner 46 of the sealing resin 4 is an example of the “third corner” of the present disclosure. The lead 26 is an example of the “first lead” of the present disclosure.

The above embodiment may have advantages as follows.

The semiconductor device A20 comprises a plurality of leads 1, a semiconductor element 3 supported by the leads 1 and electrically connected to at least one of the leads 1, and a sealing resin 4 covering a part of each lead 1 and at least a part of the semiconductor element 3. The sealing resin 4 is rectangular as viewed in the thickness direction z, and has a bottom face 42, a first side face 431, a second side face 432, a third side face 433, a fourth side face 434, and four corners 45-48. The corners 45 and 46 are located on the x1 side of the sealing resin 4 in the the first direction x, while the corners 47 and 48 are located on the x2 side of the sealing resin 4 in the first direction x. As viewed in the thickness direction z, the center C1 of the semiconductor element 3 is offset toward the x1 direction of the first direction x with respect to the center C2 of the sealing resin 4. The leads 1 include a lead 26 (first lead) located closest to the corner 45 (first corner). The lead 26 has a reverse surface 262 exposed from the bottom face 42 of the sealing resin 4, an end face 263 connected to this reverse surface 262 and exposed from the first side face 431 of the sealing resin 4, and an end face 264 connected to the reverse surface 262 and exposed from the third side face 433 of the sealing resin 4. The area S3 of the reverse surface 262 of the lead 26 is larger than the areas S22 and S23 of the reverse surfaces 242 and 212 of the leads 24 and 21 located adjacent to the lead 26. Further, the area S3 of the reverse surface 262 of the lead 26 is larger than the area S24 of the reverse surface 252 of the lead 25 located closest to the corner 47 (second corner). The area S3 of the reverse surface 262 of the lead 26 is larger than the area S25 of the reverse surface 252 of the lead 25 located closest to the corner 48 (second corner). With the above configurations, when mounting the semiconductor device A20 on a wiring circuit board, it is possible to provide a relatively large solder joint at the reverse surface 262 or the end faces 263, 264 of the lead 26 closest to the corner 45 present in the direction in which the semiconductor element 3 is offset with respect to the sealing resin 4. As a result, during the mounting process of the semiconductor device A20, stress concentration at the solder joint present in the offset direction of the semiconductor element 3 can be suppressed, thereby improving the device mounting reliability by solder bonding.

In the semiconductor device A20, as viewed in the thickness direction z, the center C1 of the semiconductor element 3 is offset from the center C2 of the sealing resin 4 in the x1 direction of the first direction x and also in the y1 direction of the second direction y. The corner 46 of the sealing resin 4 is located on the x1 side of the first direction x and on the y2 side of the second direction y. The area S3 of the reverse surface 262 of the lead 26 (first lead) is larger than the area S26 of the reverse surface 252 of the lead 25 located closest to the corner 46 (third corner). With the above configurations, when mounting semiconductor device A20, solder stress concentration is more appropriately suppressed in the vicinity of the corner 45 present in the direction in which the semiconductor element 3 is offset (the x1 side of the first direction x and the x2 side of the first direction x), which is more desirable for improving mounting reliability.

### First Variation of Second Embodiment

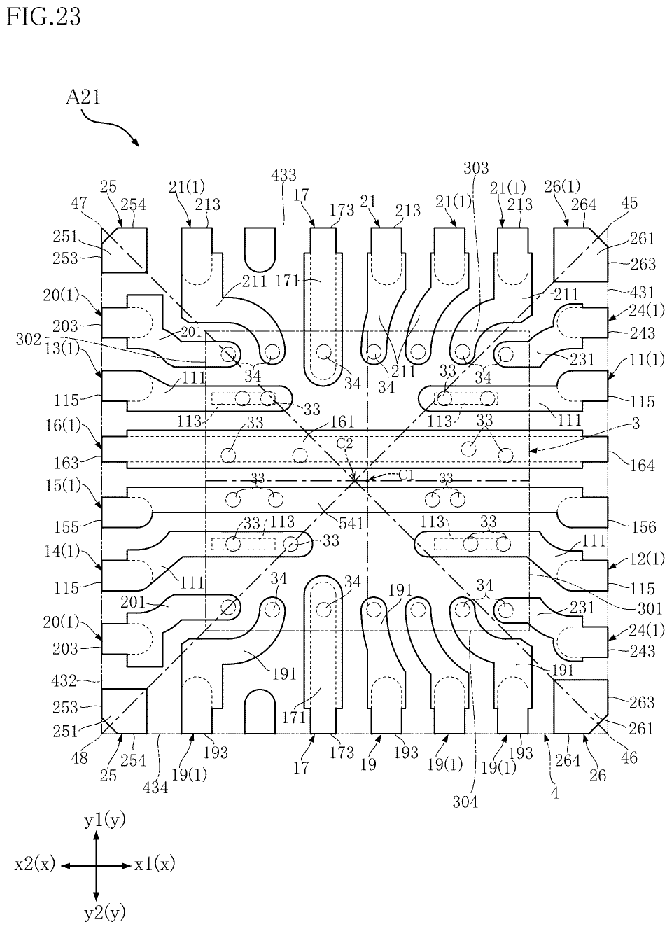

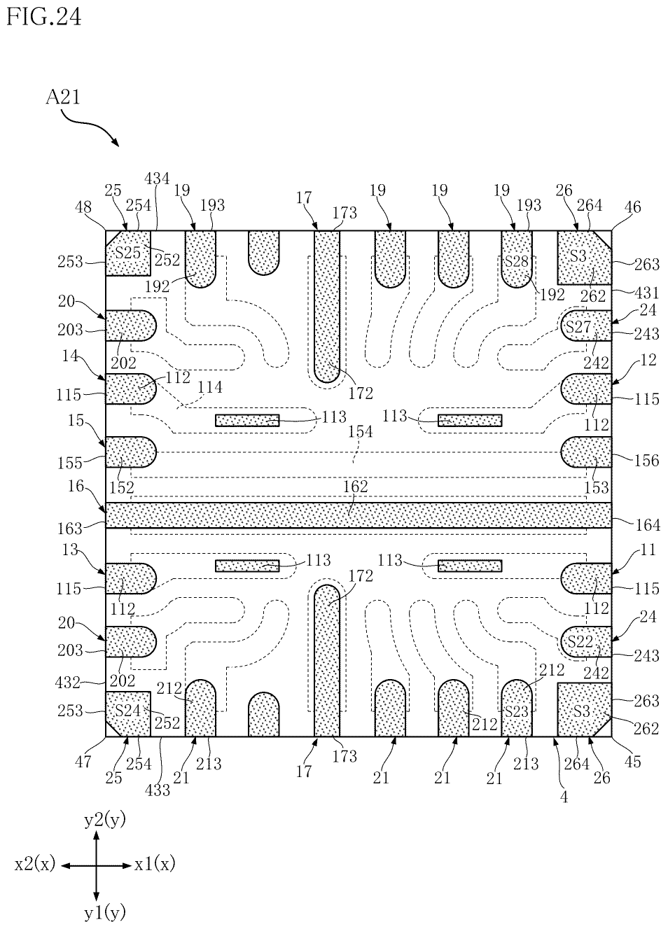

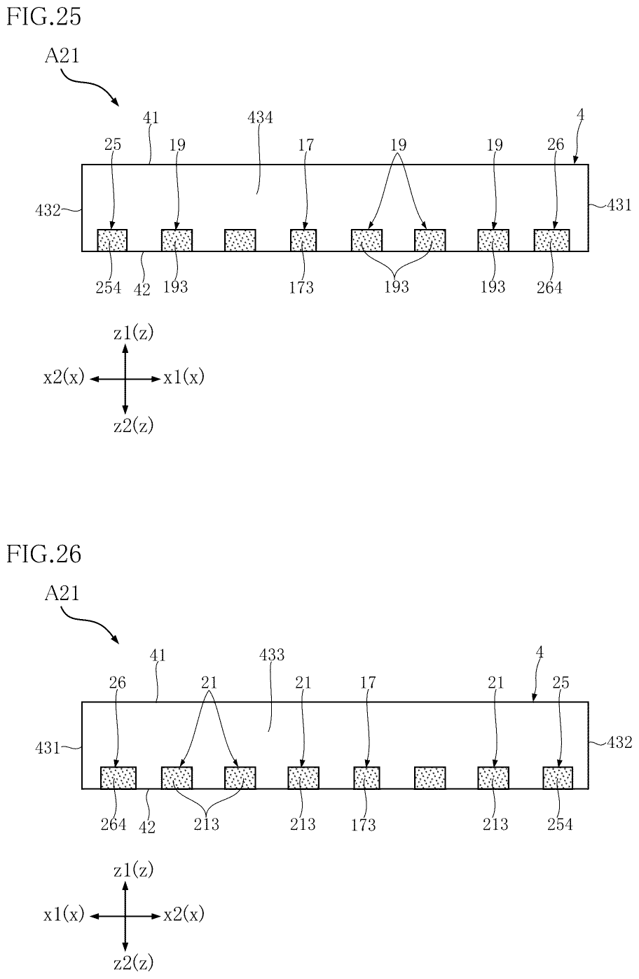

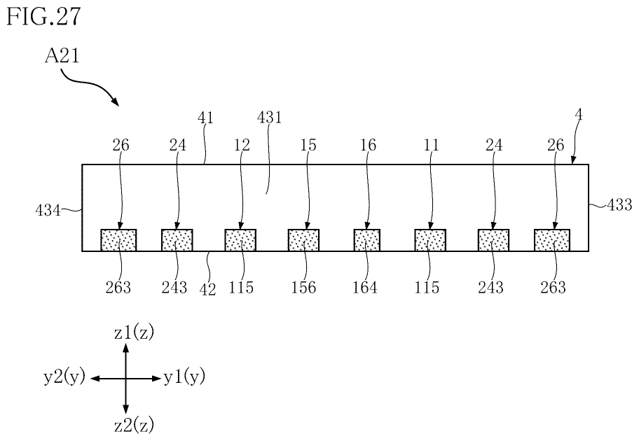

FIGS. 23-27 show a semiconductor device according to a first variation of the second embodiment. FIG. 23 is a plan view of the semiconductor device A21 of this variation. FIG. 24 is a bottom view of the semiconductor device A21. FIG. 25 is a front view of the semiconductor device A21. FIG. 26 is a rear view of the semiconductor device A21. FIG. 27 is a right side view of the semiconductor device A21. For ease of understanding, the semiconductor element 3 and the sealing resin 4 are depicted as being transparent in FIG. 23, and the transparent semiconductor element 3 and the sealing resin 4 are shown by imaginary lines (two-dot lines).

In the semiconductor device A21 of this variation, the arrangement of the semiconductor element 3 relative to the sealing resin 4 differs from that in the semiconductor device A20 of the second embodiment. In addition, the configuration and shapes of the leads 1 differ from those in the semiconductor device A20. In this variation, as viewed in the thickness direction z, the center C1 of the semiconductor element 3 is offset toward the x1 direction of the first direction x with respect to the center of the sealing resin 4. On the other hand, in the second direction y, the center C1 of the semiconductor element 3 is not offset relative to the center C2 of the sealing resin 4. The center C1 of the semiconductor element 3 and the center C2 of the sealing resin 4 are located at the center of the semiconductor device A21 in the second direction y as viewed in the thickness direction z.

In the present variation, the leads 1 include a plurality of leads 11, 12, 13, 14, a lead 15, a lead 16, a pair of leads 17, a plurality of leads 19, a plurality of leads 20, a plurality of leads 21, a plurality of leads 24, a plurality of leads 25 and a plurality of leads 26. Further, in the semiconductor device A21, the leads 1 include two leads 24. The two leads 24 are disposed on the x1 side of the first direction x in the semiconductor device A21, as shown in FIGS. 23 and 24. In the second direction y, the two leads 24 are disposed on the y1 side and the y2 side, respectively.

In the illustrated semiconductor device A21, the leads 1 include two leads 25. In the semiconductor device A21, one of the leads 25 is disposed on the x2 side of the first direction x and on the y1 side of the second direction y, while the other of the leads 25 is disposed on the x2 side of the first direction x and on the y2 side of the second direction y.

In the illustrated semiconductor device A21, the leads 1 include two leads 26, which are disposed at a corner on the x1 side of the first direction x and on the y1 side of the second direction y, and at another corner on the x1 side of the first direction x and on the y2 side of the second direction y. One of the leads 26 is located closest to the corner 45 among all the leads 1, and the other of the leads 26 is located closest to the corner 46 among all the leads 1. The two leads 24 are disposed adjacent to the two leads 26, respectively.

As shown in FIG. 24, the area S3 of the reverse surface 262 of one lead 26 located on the y1 side in the second direction y is larger than the area S22 of the reverse surface 242 of the lead 24 located adjacent to the one lead 26 in the second direction y. Further, the area S3 of the reverse surface 262 of the one lead 26 is larger than the area S23 of the reverse surface 212 of the lead 21 located closest to the corner 45 among the leads 21. This closest lead 21 is located adjacent to the one lead 26 in the first direction x.

The area S3 of the reverse surface 262 of the other lead 26 located on the y2 side in the second direction y is larger than the area S27 of the reverse surface 242 of the lead 24 located adjacent to the other lead 26 in the second direction y. The area S3 of the reverse surface 262 of the other lead 26 is larger than the area S28 of the reverse surface 192 of the lead 19 located closest to the corner 46 among the leads 19.

The area S3 of the reverse surface 262 of each of the two leads 26 is larger than the area S24 of the reverse surface 252 of the lead 25 closest to the corner 47. This closest lead 25 is closest to the corner 47 among the leads 1. The area S3 of the reverse surface 262 of each of the two leads 26 is larger than the area S25 of the reverse surface 252 of the lead 25 closest to the corner 48. This closest lead 25 is closest to the corner 48 among the leads 1.

In the above configurations, the corner 45 of the sealing resin 4 is an example of the “first corner” of the present disclosure, the corners 47 and 48 of the sealing resin 4 are examples of the “second corner(s)” of the present disclosure, and the corner 46 of the sealing resin 4 is an example of the “third corner” of the present disclosure. The two leads 26 are examples of the “first lead(s)” of the present disclosure.

The semiconductor device A21 comprises a plurality of leads 1, a semiconductor element 3 supported by the leads 1 and electrically connected to at least one of the leads 1, and a sealing resin 4 covering a part of each lead 1 and at least a part of the semiconductor element 3. The sealing resin 4 is rectangular as viewed in the thickness direction z and has a bottom face 42, a first side face 431, a second side face 432, a third side face 433, a fourth side face 434, and four corners 45-48. The corners 45 and 46 are located on the x1 side of the first direction x in the sealing resin 4, while the corners 47 and 48 are located on the x2 side of the first direction x in the sealing resin 4. As viewed in the thickness direction z, the center C1 of the semiconductor element 3 is offset toward the x1 direction of the first direction x with respect to the center C2 of the sealing resin 4. The leads 1 include two leads 26 (first leads) located closest to the corners 45 and 46 (first corners), respectively. The lead 26 has a reverse surface 262 exposed from the bottom face 42 of the sealing resin 4, an end face 263 connected to the reverse surface 262 and exposed from the first side face 431 of the sealing resin 4, and an end face 264 connected to the reverse surface 262 and exposed from the third side face 433 or the fourth side face 434 of the sealing resin 4. The area S3 of the reverse surface 262 of the one lead 26 located on the y1 side in the second direction y is larger than the areas S22 and S23 of the reverse surfaces 242 and 212 of the leads 24 and 21 located adjacent to the one lead 26. The area S3 of the reverse surface 262 of the other lead 26 located on the y2 side in the second direction y is larger than the areas S27 and S28 of the reverse surfaces 242 and 192 of the leads 24 and 19 located adjacent to the other lead 26. The area S3 of the reverse surface 262 of each lead 26 is larger than the area S24 of the reverse surface 252 of the lead 25 located closest to the corner 47 (second corner). The area S3 of the reverse surface 262 of each lead 26 is larger than the area S25 of the reverse surface 252 of the lead 25 located closest to the corner 48 (second corner). With the above configurations, when mounting the semiconductor device A21 on a wiring circuit board, it is possible to provide a relatively large solder joint at the reverse surfaces 262 and the end faces 263 and 264 of the two leads 26 closest to the corners 45 and 46 present in the direction in which the semiconductor element 3 is offset with respect to the sealing resin 4. As a result, during the mounting process of the semiconductor device A21, stress concentration at the solder joint present in the offset direction of the semiconductor element 3 can be suppressed, thereby improving the device mounting reliability by solder bonding.

In the variation shown in FIGS. 23 and 24, the lead 26 closest to the corner 45 (first corner) of the sealing resin 4 and the lead 26 closest to the corner 46 (first corner) may both correspond to the “first lead(s)” of the present disclosure, though the present disclosure is not limited to this. Only one of the two leads 26 may correspond to the first lead of the present disclosure. In this case, the area of the reverse surface 262 of one of the two leads 26 may be relatively large as described above.

The semiconductor device of the present disclosure is not limited to the embodiments described above. The specific configurations of various parts of the semiconductor device of the present disclosure may be varied in many ways.

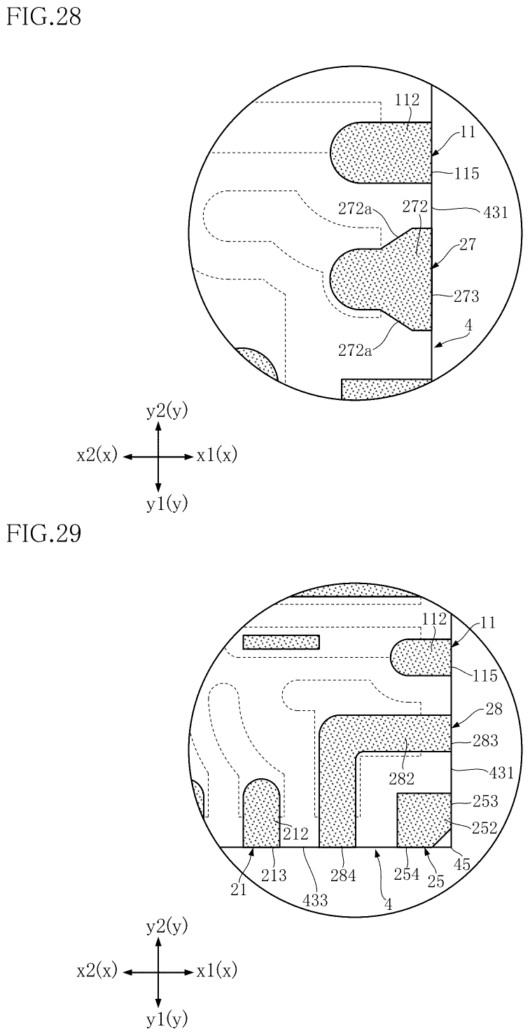

In the first embodiment described above, as shown in FIGS. 9 and 10, the width and depth dimensions of the leads 22, 23 (first leads) are larger than those of leads, for example, that are located adjacent thereto, though the present disclosure is not limited to this. Only the width dimension of the first lead may be greater than the width dimension of the adjacent lead, or the depth dimension of the first lead may be greater than the depth dimension of the adjacent lead. The shape of the reverse surface of the first lead can vary in various ways. For example, as shown in FIG. 28, the width dimension of the first lead may not be constant. In the example shown in FIG. 28, the lead 27 as a first lead has a reverse surface 272 and an end face 273, and a pair of inclined portions 272a are formed on the reverse surface 272. The two inclined portions 272a are spaced apart from each other in the width direction (second direction y) and are inclined so that their dimension in the width direction (second direction y) decreases as proceeding away from the end face 273 in the depth direction (first direction x). As shown in FIG. 29, in the first lead electrically connected to the semiconductor element, an end face(s) connected to the reverse surface may be exposed from two different side faces of the sealing resin. In the example shown in FIG. 29, the lead 28 as a first lead has a reverse surface 282, and end faces 283 and 284 connected to the reverse surface 282. One end face 283 is exposed from the first side face 431 of the sealing resin 4, while the other end face 283 is exposed from the third side face 433 of the sealing resin 4. The present disclosure includes the configurations presented in the following clauses.

Clause 1. A semiconductor device comprising:
a plurality of leads each including an obverse surface facing one side of a thickness direction, a reverse surface facing another side of the thickness direction, and an end face connected to the reverse surface and facing in a direction perpendicular to the thickness direction;
a semiconductor element supported on the obverse surfaces of the leads and electrically connected to at least one of the leads; and
a sealing resin covering a part of each of the leads and at least a part of the semiconductor element,
wherein the sealing resin is rectangular as viewed in the thickness direction and includes a first corner on one side of a first direction perpendicular to the thickness direction, a second corner on another side of the first direction, a bottom face facing the another side of the thickness direction, a first side face connected to the bottom face and facing the one side of the first direction, a second side face connected to the bottom face and facing the another side of the first direction, a third side face connected to the bottom face and facing one side of a second direction perpendicular to the thickness direction and the first direction, and a fourth side face connected to the bottom face and facing another side of the second direction,
in each of the leads, the obverse surface is covered by the sealing resin, and the reverse surface is exposed from the bottom face,
as viewed in the thickness direction, a center of the semiconductor element is offset toward the one side of the first direction with respect to a center of the sealing resin,
the leads includes a first lead closest to the first corner and electrically connected to the semiconductor element,
the end face of the first lead is exposed from at least one of the first side face, the third side face and the fourth side face,
an area of the reverse surface of the first lead is greater than an area of the reverse surface of one of the leads that is adjacent to the first lead and electrically connected to the semiconductor element, or than an area of the reverse surface of one of the leads that is closes to the second corner and electrically connected to the semiconductor element.

Clause 2. The semiconductor device according to clause 1, wherein the area of the reverse surface of the first lead is greater than the area of the reverse surface of the one of the leads that is adjacent to the first lead and electrically connected to the semiconductor element.

Clause 3. The semiconductor device according to clause 1, wherein the area of the reverse surface of the first lead is greater than an area of the reverse surface of one of the leads that is closest to the second corner and electrically connected to the semiconductor element.

Clause 4. The semiconductor device according to clause 3, wherein the lead closest to the second corner and electrically connected to the semiconductor element is line-symmetrical in location to the first lead, as viewed in the thickness direction, with respect to a straight line passing through the center of the sealing resin and extending along the second direction.

Clause 5. The semiconductor device according to clause 3, wherein the lead closest to the second corner and electrically connected to the semiconductor element is point-symmetrical in location to the first lead, as viewed in the thickness direction, with respect to the center of the sealing resin.

Clause 6. The semiconductor device according to any one of clauses 1 to 5, wherein the first corner is on the one side of the first direction and on the one side of the second direction for the sealing resin,
as viewed in the thickness direction, the center of the semiconductor element is offset toward the one side of the first direction and the one side of the second direction with respect to the center of the sealing resin.

Clause 7. The semiconductor device according to clause 6, wherein the sealing resin includes a third corner on the one side of the first direction and on the another side of the second direction,
the area of the reverse surface of the first lead is greater than the area of the reverse surface of one of the leads that is located closest to the third corner and electrically connected to the semiconductor element.

Clause 8. The semiconductor device according to clause 1, wherein the reverse surface of the first lead has a width dimension along the end face as viewed in the thickness direction, and the width dimension is greater than a width dimension of the reverse surface of the lead adjacent to the first lead and electrically connected to the semiconductor element, or than a width dimension of the reverse surface of the lead closest to the second corner and electrically connected to the semiconductor element.

Clause 9. The semiconductor device according to clause 1, wherein the reverse surface of the first lead has a depth dimension along a direction perpendicular to the end face as viewed in the thickness direction, and the depth dimension is greater than a depth dimension of the reverse surface of the lead adjacent to the first lead and electrically connected to the semiconductor element, or than a depth dimension of the reverse surface of the lead closest to the second corner and electrically connected to the semiconductor element.

Clause 10. A semiconductor device comprising:
a plurality of leads each including an obverse surface facing one side of a thickness direction, a reverse surface facing another side of the thickness direction, and an end face connected to the reverse surface and facing in a direction perpendicular to the thickness direction;
a semiconductor element supported on the obverse surfaces of the leads and electrically connected to at least one of the leads; and
a sealing resin covering a part of each of the leads and at least a part of the semiconductor element,
wherein the sealing resin is rectangular as viewed in the thickness direction and includes a first corner on one side of a first direction perpendicular to the thickness direction, a second corner on another side of the first direction, a bottom face facing the another side of the thickness direction, a first side face connected to the bottom face and facing the one side of the first direction, a second side face connected to the bottom face and facing the another side of the first direction, a third side face connected to the bottom face and facing one side of a second direction perpendicular to the thickness direction and the first direction, and a fourth side face connected to the bottom face and facing another side of the second direction,
in each of the leads, the obverse surface is covered by the sealing resin, and the reverse surface is exposed from the bottom face,
as viewed in the thickness direction, a center of the semiconductor element is offset toward the one side of the first direction with respect to a center of the sealing resin,
the leads includes a first lead closest to the first corner,
the end face of the first lead is exposed from at least one of the first side face, the third side face and the fourth side face,
an area of the reverse surface of the first lead is greater than an area of the reverse surface of one of the leads that is adjacent to the first lead, or than an area of the reverse surface of one of the leads that is closest to the second corner.

Clause 11. The semiconductor device according to clause 10, wherein the area of the reverse surface of the first lead is greater than the area of the reverse surface of the one of the leads that is adjacent to the first lead.

Clause 12. The semiconductor device according to clause 10, wherein the area of the reverse surface of the first lead is greater than an area of the reverse surface of one of the leads that is closest to the second corner.

Clause 13. The semiconductor device according to any one of clauses 10 to 12, wherein the first corner is on the one side of the first direction and on the one side of the second direction for the sealing resin,
as viewed in the thickness direction, the center of the semiconductor element is offset toward the one side of the first direction and the one side of the second direction with respect to the center of the sealing resin.

Clause 14. The semiconductor device according to clause 13, wherein the sealing resin includes a third corner on the one side of the first direction and on the another side of the second direction,
the area of the reverse surface of the first lead is greater than the area of the reverse surface of one of the leads that is located closest to the third corner.

Clause 15. The semiconductor device according to any one of clauses 1 to 14, wherein the semiconductor element is provided with a plurality of electrodes on a side facing the obverse surface in the thickness direction,
the electrodes are connected to the obverse surfaces of the leads.

REFERENCE NUMERALS

A10, A11, A20, A21: Semiconductor device
1, 11, 12, 13, 14, 15, 16, 17, 18, 19, 20, 21, 24, 25: Lead
22, 23, 26, 27, 28: Lead (First lead)
111, 151, 161, 171, 181, 191: Obverse surface
201, 211, 221, 231, 241, 251, 261: Obverse surface
112, 113, 152, 153, 162, 172, 182, 183, 184, 192: Reverse surface
202, 212, 222, 232, 242, 252, 262, 272, 282: Reverse surface
114, 154: Concave surface
115, 155, 156, 163, 164, 173, 185, 186, 187, 188, 193: End face
203, 213, 223, 233, 243, 253, 254, 263, 264, 273, 283, 284: End face
272a: Inclined portion 3: Semiconductor element
301: First element side surface 302: Second element side surface
303: Third element side surface 304: Fourth element side surface
31: Semiconductor substrate 32: Semiconductor layer
321: Switching circuit 322: Control circuit 33, 34: Electrode 4: Sealing
resin
41: Top face 42: Bottom face 431: First side face 432: Second side face
433: Third side face 434: Fourth side face 45: Corner (First corner)
46: Corner (First corner, Third corner) 47, 48: Corner (Second corner)
C1: Center (of semiconductor element) C2: Center (of sealing resin)
L1, L2, L3, L11, L12, L13, L14: Dimension
S1, S2, S3, S4, S11, S12, S13, S14, S15, S16, S17: Area
S18, S19, S21, S22, S23, S24, S25, S26, S27, S28: Area

1. A semiconductor device comprising:
a plurality of leads each including an obverse surface facing one side of a thickness direction, a reverse surface facing another side of the thickness direction, and an end face connected to the reverse surface and facing in a direction perpendicular to the thickness direction;
a semiconductor element supported on the obverse surfaces of the leads and electrically connected to at least one of the leads; and
a sealing resin covering a part of each of the leads and at least a part of the semiconductor element,
wherein the sealing resin is rectangular as viewed in the thickness direction and includes a first corner on one side of a first direction perpendicular to the thickness direction, a second corner on another side of the first direction, a bottom face facing the another side of the thickness direction, a first side face connected to the bottom face and facing the one side of the first direction, a second side face connected to the bottom face and facing the another side of the first direction, a third side face connected to the bottom face and facing one side of a second direction perpendicular to the thickness direction and the first direction, and a fourth side face connected to the bottom face and facing another side of the second direction,
in each of the leads, the obverse surface is covered by the sealing resin, and the reverse surface is exposed from the bottom face,
as viewed in the thickness direction, a center of the semiconductor element is offset toward the one side of the first direction with respect to a center of the sealing resin,
the leads includes a first lead closest to the first corner and electrically connected to the semiconductor element,
the end face of the first lead is exposed from at least one of the first side face, the third side face and the fourth side face,
an area of the reverse surface of the first lead is greater than an area of the reverse surface of one of the leads that is adjacent to the first lead and electrically connected to the semiconductor element, or than an area of the reverse surface of one of the leads that is closes to the second corner and electrically connected to the semiconductor element.

2. The semiconductor device according to claim 1, wherein the area of the reverse surface of the first lead is greater than the area of the reverse surface of the one of the leads that is adjacent to the first lead and electrically connected to the semiconductor element.

3. The semiconductor device according to claim 1, wherein the area of the reverse surface of the first lead is greater than an area of the reverse surface of one of the leads that is closest to the second corner and electrically connected to the semiconductor element.

4. The semiconductor device according to claim 3, wherein the lead closest to the second corner and electrically connected to the semiconductor element is line-symmetrical in location to the first lead, as viewed in the thickness direction, with respect to a straight line passing through the center of the sealing resin and extending along the second direction.

5. The semiconductor device according to claim 3, wherein the lead closest to the second corner and electrically connected to the semiconductor element is point-symmetrical in location to the first lead, as viewed in the thickness direction, with respect to the center of the sealing resin.

6. The semiconductor device according to claim 1, wherein the first corner is on the one side of the first direction and on the one side of the second direction for the sealing resin,
as viewed in the thickness direction, the center of the semiconductor element is offset toward the one side of the first direction and the one side of the second direction with respect to the center of the sealing resin.

7. The semiconductor device according to claim 6, wherein the sealing resin includes a third corner on the one side of the first direction and on the another side of the second direction,
the area of the reverse surface of the first lead is greater than the area of the reverse surface of one of the leads that is located closest to the third corner and electrically connected to the semiconductor element.

8. The semiconductor device according to claim 1, wherein the reverse surface of the first lead has a width dimension along the end face as viewed in the thickness direction, and the width dimension is greater than a width dimension of the reverse surface of the lead adjacent to the first lead and electrically connected to the semiconductor element, or than a width dimension of the reverse surface of the lead closest to the second corner and electrically connected to the semiconductor element.

9. The semiconductor device according to claim 1, wherein the reverse surface of the first lead has a depth dimension along a direction perpendicular to the end face as viewed in the thickness direction, and the depth dimension is greater than a depth dimension of the reverse surface of the lead adjacent to the first lead and electrically connected to the semiconductor element, or than a depth dimension of the reverse surface of the lead closest to the second corner and electrically connected to the semiconductor element.

10. A semiconductor device comprising:
a plurality of leads each including an obverse surface facing one side of a thickness direction, a reverse surface facing another side of the thickness direction, and an end face connected to the reverse surface and facing in a direction perpendicular to the thickness direction;
a semiconductor element supported on the obverse surfaces of the leads and electrically connected to at least one of the leads; and
a sealing resin covering a part of each of the leads and at least a part of the semiconductor element,
wherein the sealing resin is rectangular as viewed in the thickness direction and includes a first corner on one side of a first direction perpendicular to the thickness direction, a second corner on another side of the first direction, a bottom face facing the another side of the thickness direction, a first side face connected to the bottom face and facing the one side of the first direction, a second side face connected to the bottom face and facing the another side of the first direction, a third side face connected to the bottom face and facing one side of a second direction perpendicular to the thickness direction and the first direction, and a fourth side face connected to the bottom face and facing another side of the second direction,
in each of the leads, the obverse surface is covered by the sealing resin, and the reverse surface is exposed from the bottom face,
as viewed in the thickness direction, a center of the semiconductor element is offset toward the one side of the first direction with respect to a center of the sealing resin,
the leads includes a first lead closest to the first corner,
the end face of the first lead is exposed from at least one of the first side face, the third side face and the fourth side face,
an area of the reverse surface of the first lead is greater than an area of the reverse surface of one of the leads that is adjacent to the first lead, or than an area of the reverse surface of one of the leads that is closest to the second corner.

11. The semiconductor device according to claim 10, wherein the area of the reverse surface of the first lead is greater than the area of the reverse surface of the one of the leads that is adjacent to the first lead.

12. The semiconductor device according to claim 10, wherein the area of the reverse surface of the first lead is greater than an area of the reverse surface of one of the leads that is closest to the second corner.

13. The semiconductor device according to claim 10, wherein the first corner is on the one side of the first direction and on the one side of the second direction for the sealing resin,
as viewed in the thickness direction, the center of the semiconductor element is offset toward the one side of the first direction and the one side of the second direction with respect to the center of the sealing resin.

14. The semiconductor device according to claim 13, wherein the sealing resin includes a third corner on the one side of the first direction and on the another side of the second direction,
the area of the reverse surface of the first lead is greater than the area of the reverse surface of one of the leads that is located closest to the third corner.

15. The semiconductor device according to claim 1, wherein the semiconductor element is provided with a plurality of electrodes on a side facing the obverse surface in the thickness direction,
the electrodes are connected to the obverse surfaces of the leads.

16. The semiconductor device according to claim 10, wherein the semiconductor element is provided with a plurality of electrodes on a side facing the obverse surface in the thickness direction,
the electrodes are connected to the obverse surfaces of the leads.
